(19) United States
(12) Patent Application Publication
(10) Pub. No.: US 2024/0405028 A1
(43) Pub. Date: Dec. 5, 2024

(54) DISPLAY DEVICE

(71) Applicant: Samsung Display Co., Ltd., Yongin-Si (KR)

(72) Inventors: Dong Il YOO, Yongin-si (KR); Jung Suk BANG, Yongin-si (KR); Min KANG, Yongin-si (KR); Myung Hun LIM, Yongin-si (KR)

(21) Appl. No.: 18/680,638

(22) Filed: May 31, 2024

(30) Foreign Application Priority Data
Jun. 2, 2023 (KR) 10-2023-0071794

(51) Int. Cl. H01L 27/12; H01L 25/16

(52) U.S. Cl. CPC H01L 27/124; H01L 25/0753; H01L 25/167; H01L 27/1248; H01L 33/62

(57) ABSTRACT

A display device may include first, second, and third sub-pixels. Each of the first, second, and third sub-pixels may include: a pixel circuit layer including first, second, and third transistors disposed on a substrate, and a bridge pattern disposed on a gate electrode of the first transistor and a source electrode of the second transistor, a first end of the bridge pattern is electrically connected to the source electrode of the second transistor and a second end of the bridge pattern is electrically connected to the gate electrode of the first transistor; first and second alignment electrodes disposed on the pixel circuit layer; and light emitting elements disposed on the first and second alignment electrodes and electrically connected to at least one of the first, second, and third transistors. The second alignment electrode may be supplied with a low potential voltage and overlap the bridge pattern in a plan view.

### CROSS-REFERENCE TO RELATED APPLICATION

The present application claims priority to Korean patent application number 10-2023-0071794 filed on Jun. 2, 2023, the entire disclosure of which is incorporated herein in its entirety by reference.

### BACKGROUND

### 1. Field of Inventive Concept

Various embodiments of the present disclosure relate to a display device.

### 2. Description of Related Art

Recently, as interest in information display increases, research and development on display devices have been continuously conducted.

### SUMMARY

Various embodiments of the present disclosure may provide a display device having improved reliability.

An embodiment of the present disclosure may provide a display device, including a first sub-pixel, a second sub-pixel, and a third sub-pixel disposed adjacent to each other. Each of the first, the second, and the third sub-pixels may include: a pixel circuit layer including a first transistor, a second transistor, and a third transistor that are disposed on a substrate, and a bridge pattern disposed on a gate electrode of the first transistor and a source electrode of the second transistor, the source electrode of the second transistor and a second end of the bridge pattern is electrically connected to the gate electrode of the first transistor; a first alignment electrode and a second alignment electrode disposed on the pixel circuit layer and spaced apart from each other; and light emitting elements disposed on the first and the second alignment electrodes and electrically connected to at least one of the first, the second, and the third transistors. The second alignment electrode may be supplied with a low potential voltage, and overlap the bridge pattern in a plan view.

In an embodiment, the pixel circuit layer may include first, second, third, fourth, and fifth insulating layers that are successively stacked on the substrate. The source electrode of the second transistor may be disposed on the first insulating layer, the gate electrode of the first transistor may be disposed on the second insulating layer, the bridge pattern may be disposed on the third insulating layer, and the second alignment electrode may be disposed on the fifth insulating layer.

In an embodiment, the first end of the bridge pattern may be electrically connected to the source electrode of the second transistor through a first contact hole formed through the second and the third insulating layers. The second end of the bridge pattern may be electrically connected to the gate electrode of the first transistor through a second contact hole formed through the third insulating layer.

In an embodiment, the second alignment electrode may overlap the first contact hole and the second contact hole.

In an embodiment, the second alignment electrode may overlap the second contact hole and does not overlaps the first contact hole.

In an embodiment, the second alignment electrode may overlap the first contact hole and does not overlap the second contact hole.

In an embodiment, each of the first, the second, and the third sub-pixels may include: a contact electrode disposed on the third insulating layer; the fourth and the fifth insulating layers disposed on the contact electrode, and each including a contactor exposing the contact electrode is exposed; and electrodes disposed on the first and the second alignment electrodes and the light emitting elements on the fifth insulating layer, and electrically connected to the light emitting elements.

In an embodiment, at least one electrode of the electrodes may be electrically connected to the contact electrode through the contactor.

In an embodiment, the electrodes may include a first electrode, a second electrode, a third electrode, a fourth electrode, and a fifth electrode spaced apart from each other. The first electrode may include an anode electrode of each of the first, the second, and the third sub-pixels, and the fifth electrode comprises a cathode electrode of the corresponding sub-pixel. The at least one electrode may include the first electrode.

In an embodiment, each of the first, the second, and the third sub-pixels may include: a first sub-electrode disposed on a layer identical to the second electrode and electrically connected to the second electrode; a second sub-electrode disposed on a layer identical to the third electrode and electrically connected to the third electrode; a third sub-electrode disposed on a layer identical to the fourth electrode and electrically connected to the fourth electrode; and a fourth sub-electrode disposed on a layer identical to the fifth electrode and electrically connected to the fifth electrode. The fourth sub-electrode of the first sub-pixel may be electrically connected to the fourth sub-electrode of the second sub-pixel.

In an embodiment, the first to the fifth electrodes and the first to the fourth sub-electrodes may include identical material.

In an embodiment the bridge pattern of the first sub-pixel, the bridge pattern of the third sub-pixel, and the bridge pattern of the second sub-pixel may be arranged sequentially in a second direction in a plan view. The second alignment electrode may have a plate shape, extending in the second direction, and overlapping the bridge pattern of the first sub-pixel, the bridge pattern of the third sub-pixel, and the bridge pattern of the second sub-pixel.

In an embodiment, in each of the first, the second, and the third sub-pixels, the gate electrode of the first transistor, the source electrode of the second transistor, and the bridge pattern that are electrically connected to each other may form a first node. The second alignment electrode may be a shielding component to block parasitic capacitance occurring between the first nodes of the sub-pixels that are disposed adjacent to each other in the second direction.

In an embodiment, the display device may further include a data line configured to transmit a data signal to each of the first, the second, and the third sub-pixels, and extending in a second direction. The data line may have a width of approximately 7 μm in a first direction intersecting the second direction.

In an embodiment, the display device may further include: a first color conversion layer disposed in the first sub-pixel, and a first color filter disposed on the first color conversion layer; a second color conversion layer disposed in the second sub-pixel, and a second color filter disposed on the second color conversion layer; and a third color conversion layer disposed in the third sub-pixel, and a third color filter disposed on the third color conversion layer.

An embodiment of the present disclosure may provide a display device, including: a substrate a substrate, a first sub-pixel, a third sub-pixel, and a second sub-pixel disposed adjacent to each other in a second direction, each including an emission area and a non-emission area, and disposed on the substrate; a first data line configured to apply a data signal to the first sub-pixel, a second data line configured to apply a data signal to the second sub-pixel, and a third data line configured to apply a data signal to the third sub-pixel; light emitting elements disposed in the respective emission areas of the first to the third sub-pixels; a first transistor, a second transistor, and a third transistor positioned between the substrate and the light emitting elements, and electrically connected to the light emitting elements; a bridge pattern electrically connecting a gate electrode of the first transistor and a source electrode of the second transistor; a first alignment electrode and a second alignment electrode positioned between the bridge pattern and the light emitting elements, and disposed to be spaced apart from each other; and electrodes disposed on the first and the second alignment electrodes, and electrically connected to the light emitting elements. The second alignment electrode may overlap the bridge pattern of the first sub-pixel, the bridge pattern of the second sub-pixel, and the bridge pattern of the third sub-pixel in a plan view.

In an embodiment, the first alignment electrode may be a floating electrode, and the second alignment electrode may be supplied with a low potential voltage.

In an embodiment, the display device may further include a first insulating layer, a second insulating layer, a third insulating layer, a fourth insulating layer, and a fifth insulating layer disposed between the substrate and the first and the second alignment electrodes, and stacked sequentially on the substrate. The source electrode of the second transistor may be disposed on the first insulating layer, the gate electrode of the first transistor may be disposed on the second insulating layer, and the bridge pattern may be disposed on the third insulating layer, and the first and the second alignment electrodes may be disposed on the fifth insulating layer. A first end of the bridge pattern may be electrically connected to the source electrode of the second transistor through a first contact hole formed through the second insulating layer and the third insulating layers. A second end of the bridge pattern may be electrically connected to the gate electrode of the first transistor through a second contact hole formed through the third insulating layer.

In an embodiment, the second alignment electrode may overlap the first contact hole and the second contact hole in a plan view.

In an embodiment, the first data line, the second data line, and the third data line may be arranged sequentially in a first direction intersecting the second direction. Each of the first data line, the second data line, and the third data line may have a width of approximately 7 μm in the first direction.

### BRIEF DESCRIPTION OF THE DRAWINGS

FIG. 1 is a schematic perspective view illustrating a light emitting element in accordance with an embodiment.

FIG. 2 is a schematic cross-sectional view illustrating the light emitting element of FIG. 1.

FIG. 3 is a schematic plan view illustrating a display device in accordance with an embodiment.

FIG. 4 is a schematic cross-sectional view illustrating each of the pixels illustrated in FIG. 3.

FIG. 5 is a schematic circuit diagram illustrating an electrical connection relationship of components included in each of the pixels illustrated in FIG. 3.

FIG. 6 is a schematic plan view illustrating a pixel circuit layer of a pixel in accordance with an embodiment.

FIG. 7 is a schematic plan view illustrating only components included in a first conductive layer in the pixel of FIG. 6.

FIG. 8 is a schematic plan view illustrating transistors and only components included in a second conductive layer in the pixel of FIG. 6.

FIG. 9 is a schematic cross-sectional view taken along line I-I′ of FIG. 6.

FIG. 10 is a schematic plan view illustrating a display element layer of a pixel in accordance with an embodiment.

FIG. 11 is a schematic plan view illustrating a first sub-pixel of FIG. 10.

FIG. 12 is a schematic cross-sectional view taken along line II-II′ of FIG. 11.

FIG. 13 is a schematic cross-sectional view illustrating the first to third sub-pixels in accordance with an embodiment.

FIG. 14 is a schematic plan view illustrating a pixel including an alignment electrode, based on the pixel of FIG. 6.

FIG. 15 is a schematic enlarged view of portion EA of FIG. 14.

FIG. 16 is a schematic cross-sectional view taken along line III-III′ of FIG. 15.

FIG. 17 is a schematic enlarged view of portion EA of FIG. 14 in accordance with another embodiment.

FIG. 18 is a schematic cross-sectional view taken along line IV-IV′ of FIG. 17.

FIG. 19 is a schematic enlarged view of portion EA of FIG. 14 in accordance with another embodiment.

FIG. 20 is a schematic cross-sectional view taken along line V-V′ of FIG. 19.

### DETAILED DESCRIPTION

As the present disclosure allows for various changes and numerous embodiments, particular embodiments will be illustrated in the drawings and described in detail in the written description. However, this is not intended to limit the present disclosure to particular modes of practice, and it is to be appreciated that all changes, equivalents, and substitutes that do not depart from the technical scope of the present disclosure are encompassed in the present disclosure.

Throughout the disclosure, like reference numerals refer to like parts throughout the various figures and embodiments of the present disclosure. The sizes of elements in the accompanying drawings may be exaggerated for clarity of illustration. It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is disposed on a second part, the first part may be not only directly on the second part but a third part may intervene between them. In addition, in case that it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be not only directly under the second part but a third part may intervene between them.

Embodiments and required details of the present disclosure are described with reference to the accompanying drawings in order to describe the present disclosure in detail so that those having ordinary knowledge in the technical field to which the present disclosure pertains can easily practice the present disclosure. Furthermore, a singular form may include a plural form as long as it is not specifically mentioned in a sentence.

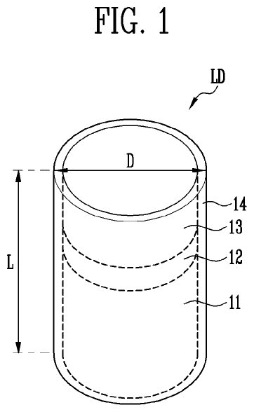

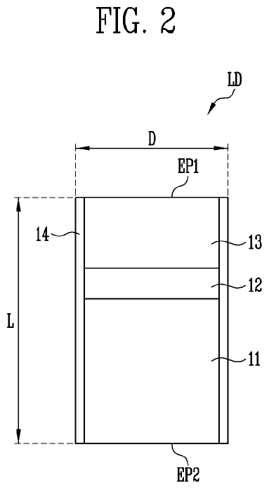

FIG. 1 is a schematic perspective view illustrating a light emitting element LD in accordance with an embodiment. FIG. 2 is a schematic cross-sectional view illustrating the light emitting element LD of FIG. 1.

Referring to FIGS. 1 and 2, the light emitting element LD may include a first semiconductor layer 11, a second semiconductor layer 13, and an active layer 12 interposed between the first and second semiconductor layers 11 and 13. For example, the light emitting element LD may be implemented as an emission stack (or referred to as “stack pattern”) formed by successively stacking the first semiconductor layer 11, the active layer 12, and the second semiconductor layer 13.

The light emitting element LD may be formed in a shape extending in one direction. If the direction in which the light emitting element LD extends is defined as a longitudinal direction, the light emitting element LD may have a first end EP1 and a second end EP2 that are opposite to each other with respect to the longitudinal direction. For example, the second semiconductor layer 13 may be disposed on the first end EP1 of the light emitting element LD, and the first semiconductor layer 11 may be disposed on the second end EP2 of the light emitting element LD. However, the present disclosure is not limited to the foregoing example.

The light emitting element LD may be provided in various shapes. For example, as illustrated in FIG. 1, the light emitting element LD may have a rod-like shape, a bar-like shape, or a pillar-like shape which is long with respect to the longitudinal direction (for example, to have an aspect ratio greater than 1). However, the present disclosure is not limited to the foregoing example.

The light emitting element LD may include a light emitting diode (LED) fabricated to have a subminiature size, e.g., with a diameter D and/or a length L corresponding to a range from the nano scale (or the nanometer scale) to the micro scale (or the micrometer scale).

In case that the light emitting element LD is long (e.g., to have an aspect ratio greater than 1) with respect to the longitudinal direction, the diameter D of the light emitting element LD may approximately range from 0.5 μm to 6 μm, and the length L thereof may approximately range from 1 μm to 10 μm. However, the diameter D and the length L of the light emitting element LD are not limited thereto. The size of the light emitting element LD may be changed to meet requirements (or design conditions) of a lighting device or a self-emissive display device to which the light emitting element LD is applied.

The first semiconductor layer 11 may include, for example, at least one n-type semiconductor layer. For instance, the first semiconductor layer 11 may include an n-type semiconductor layer which includes at least one semiconductor material of InAlGaN, GaN, AlGaN, InGaN, AlN, and InN and is doped with a first conductive dopant (or an n-type dopant) such as Si, Ge, or Sn. However, the constituent material of the first semiconductor layer 11 is not limited to thereto, and various other materials may be used to form the first conductive semiconductor layer 11.

The active layer 12 may be disposed on the first semiconductor layer 11 and have a single- or multi-quantum well structure. The active layer 12 may emit light having a wavelength ranging from 400 nm to 900 nm, and have a double hetero structure. In an embodiment, a clad layer doped with a conductive dopant may be formed over or under the active layer 12 with respect to the longitudinal direction of the light emitting element LD.

If an electric field having a certain voltage or more is applied between the opposite ends of the light emitting element LD, the light emitting element LD may emit light by coupling of electron-hole pairs in the active layer 12. Because light emission of the light emitting element LD can be controlled based on the foregoing principle, the light emitting element LD may be used as a light source (a light emitting source) of various light emitting devices as well as a pixel of a display device.

The second semiconductor layer 13 may be disposed on the active layer 12 and include a semiconductor layer of a type different from that of the first semiconductor layer 11. For example, the second semiconductor layer 13 may include at least one p-type semiconductor layer. For instance, the second semiconductor layer 13 may include a p-type semiconductor layer which includes at least one semiconductor material of InAlGaN, GaN, AlGaN, InGaN, AlN, and InN, and is doped with a second conductive dopant (or a p-type dopant) such as Mg, Zn, Ca, Sr, or Ba. However, the material for forming the second semiconductor layer 13 is not limited thereto, and various other materials may be used to form the second semiconductor layer 13.

The first semiconductor layer 11 and the second semiconductor layer 13 may have different thicknesses with respect to the longitudinal direction of the light emitting element LD. For example, the first semiconductor layer 11 may have a thickness greater than that of the second semiconductor layer 13 with respect to the longitudinal direction of the light emitting element LD, but the present disclosure is not limited thereto.

In an embodiment, the light emitting element LD may further include a contact electrode (hereinafter referred to as “first contact electrode”) disposed over the second semiconductor layer 13, as well as including the first semiconductor layer 11, the active layer 12, and the second semiconductor layer 13. Furthermore, in an embodiment, the light emitting element LD may further include an additional contact electrode (hereinafter referred to as “second contact electrode”) disposed on one end of the first semiconductor layer 11. Each of the first and second contact electrodes may be an ohmic contact electrode, but the present disclosure is not limited thereto. In an embodiment, each of the first and second contact electrodes may be a Schottky contact electrode. The first and second contact electrodes may include conductive material.

In an embodiment, the light emitting element LD may further include an insulating film 14. However, depending on the embodiment, the insulating film 14 may be omitted, or may be provided to cover only some of the first semiconductor layer 11, the active layer 12, and the second semiconductor layer 13.

The insulating film 14 may prevent the active layer 12 from short-circuiting due to making contact with conductive material except the first and second semiconductor layers 11 and 13. Furthermore, the insulating film 14 may minimize a surface defect of the light emitting element LD, thus enhancing the lifetime and emission efficiency of the light emitting element LD. In the case in which a plurality of light emitting elements LD are disposed in close contact with each other, the insulating film 14 may prevent an undesired short-circuit from occurring between the light emitting elements LD. The presence or non-presence of the insulating film 14 is not limited, so long as the active layer 12 can be prevented from short-circuiting with external conductive material.

The insulating film 14 may be provided to enclose an overall outer circumferential surface of the emission stack including the first semiconductor layer 11, the active layer 12, and the second semiconductor layer 13.

The insulating film 14 may include transparent insulating material. Various materials having insulation properties may be used as the material of the insulating film 14. The insulating film 14 may have a single-layer structure or a multilayer structure including a double-layer structure.

In an embodiment, the light emitting element LD may be implemented as a light emitting pattern having a core-shell structure.

The light emitting element LD may be employed as a light emitting source (or a light source) for various display devices. The light emitting element LD may be fabricated through a surface treatment process.

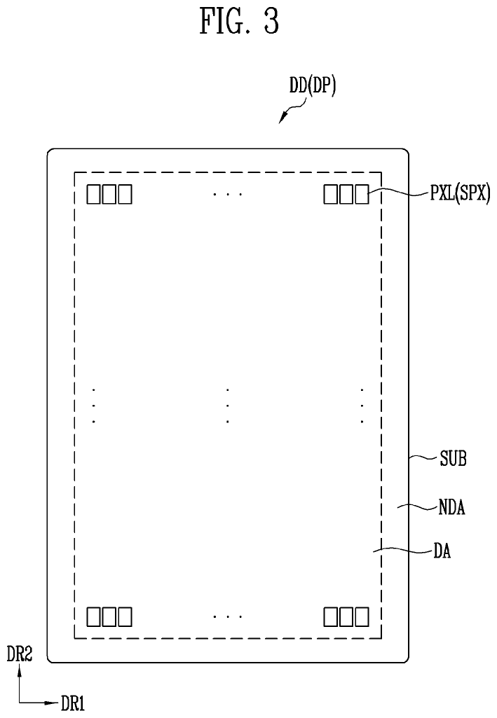

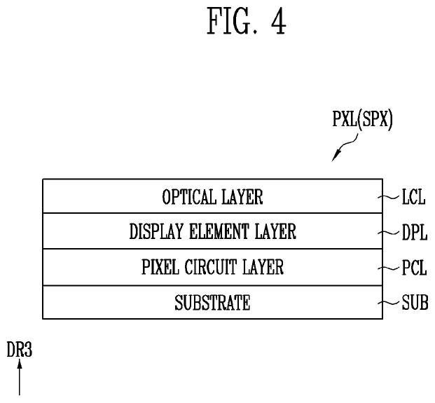

FIG. 3 is a schematic plan view illustrating a display device DD in accordance with an embodiment. FIG. 4 is a schematic cross-sectional view illustrating each of the pixels PXL illustrated in FIG. 3.

In FIGS. 3 and 4, for the convenience sake, there is schematically illustrated the display device DD, for example, the structure of a display panel DP provided in the display device DD, centered on a display area DA in which an image is displayed.

Referring to FIGS. 1 to 4, the display device DD may be classified into a passive matrix type display device and an active matrix type display device according to a method of driving the light emitting element LD. For example, in case that the display device DD is implemented as an active matrix type display device, each of the pixels PXL may include a driving transistor configured to control the amount of current to be supplied to the light emitting element LD, and a switching transistor configured to transmit data signals to the driving transistor.

The display panel DP (or the display device DD) may include pixels PXL disposed on a substrate SUB. Each of the pixels PXL may include at least one light emitting element LD.

The substrate SUB may include transparent insulating material to allow light transmission. The substrate SUB may be a rigid substrate or a flexible substrate.

For example, the rigid substrate may be one of a glass substrate, a quartz substrate, a glass ceramic substrate, and a crystalline glass substrate.

The flexible substrate may be either a film substrate or a plastic substrate which includes polymer organic material. For example, the flexible substrate SUB may include at least one of the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

One area of the substrate SUB may be provided as the display area DA in which the pixels PXL are disposed, and the other area of the substrate SUB may be provided as the non-display area NDA.

The display area DA may be an area in which the pixels PXL for displaying an image are disposed.

The non-display area NDA may be disposed adjacent to the display area DA. The non-display area NDA may be provided on at least one side of the display area DA. For example, the non-display area NDA may enclose the perimeter (or edges) of the display area DA. In the non-display area NDA, there may be placed a driver for driving each pixel PXL and signal lines for connecting each pixel PXL to the driver.

The pixels PXL may be provided in the display area DA on the substrate SUB. The pixels PXL may be arranged in the display area DA in a stripe arrangement manner or the like, but the present disclosure is not limited thereto.

Each pixel PXL may include a pixel circuit layer PCL, a display element layer DPL, and an optical layer LCL which are disposed on the substrate SUB.

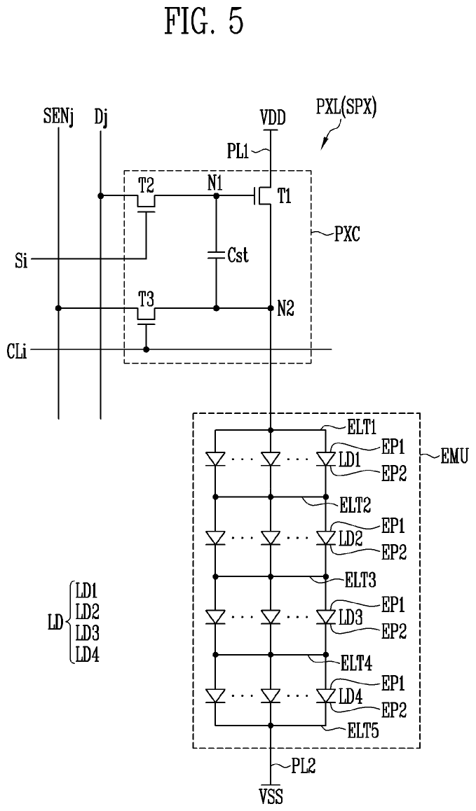

A pixel circuit (refer to “PXC” of FIG. 5) which is provided on the substrate SUB and includes a plurality of transistors and signal lines electrically connected to the transistors may be disposed in the pixel circuit layer PCL.

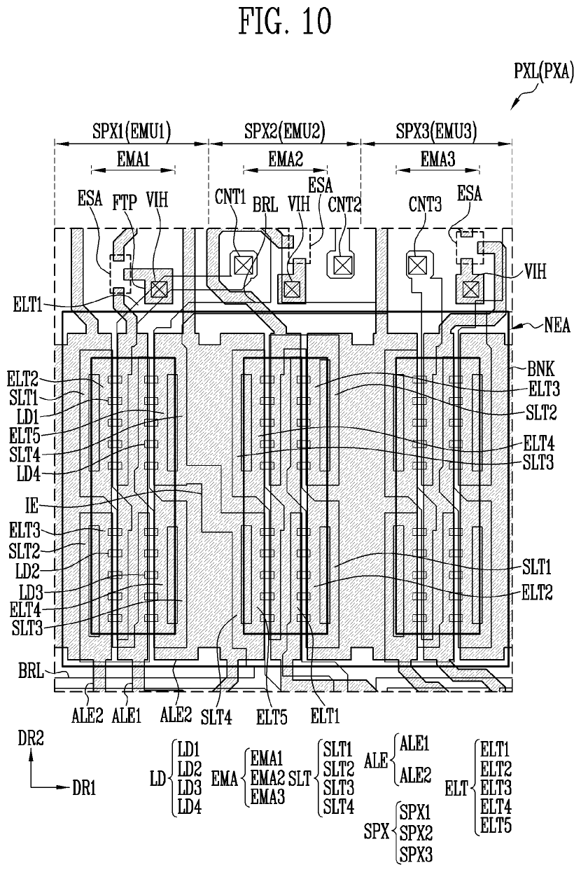

The display element layer DPL may be disposed on the pixel circuit layer PCL. An emission component (refer to “EMU” of FIG. 5) including a light emitting element LD configured to emit light may be disposed in the display element layer DPL. In the emission component EMU, there may be disposed electrodes (refer to FIG. 10) electrically connected to the light emitting element LD.

The optical layer LCL may be disposed on the display element layer DPL. The optical layer LCL may convert light emitted from the light emitting element LD to light having excellent color reproducibility and emit the converted light, thus enhancing the light output efficiency of each pixel PXL. In an embodiment, the optical layer LCL may include a color conversion layer, a color filter, and the like, but the present disclosure is not limited thereto.

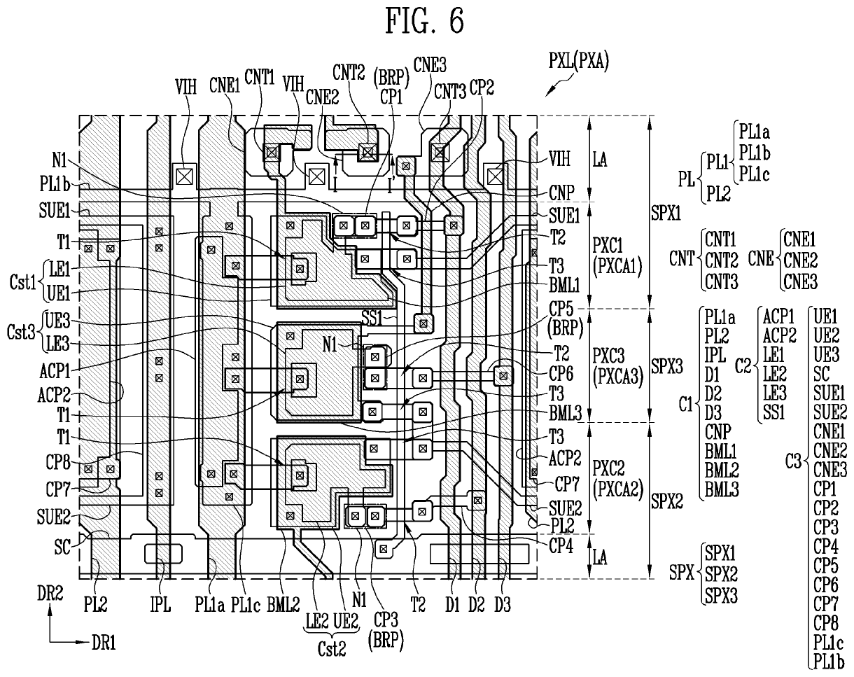

In a certain area of the display area DA, e.g., the pixel area, in which the pixels PXL are provided, there may be provided a plurality of sub-pixels SPX, for example, a first sub-pixel (refer to “SPX1” of FIG. 6), a second sub-pixel (refer to “SPX2” of FIG. 6), and a third sub-pixel (refer to “SPX3” of FIG. 6). The first sub-pixel SPX1 may be a red pixel. The second sub-pixel SPX2 may be a green pixel. The third sub-pixel SPX3 may be a blue pixel. However, the present disclosure is not limited to the aforementioned examples. The first sub-pixel SPX1 may include a first pixel circuit and a first emission component. The second sub-pixel SPX2 may include a second pixel circuit and a second emission component. The third sub-pixel SPX3 may include a third pixel circuit and a third emission component.

The first, second, and third pixel circuits and the first, second, and third emission components may be disposed on difference layers and overlap each other. For example, the first, second, and third pixel circuits may be disposed in the pixel circuit layer PCL of each sub-pixel SPX. The first, second, and third emission components may be disposed in the display element layer DPL that overlaps the pixel circuit layer PCL in the corresponding sub-pixel SPX.

FIG. 5 is a schematic circuit diagram illustrating an electrical connection relationship of components included in each of the pixels PXL illustrated in FIG. 3.

For example, FIG. 5 illustrates the electrical connection relationship of components included in the pixel PXL (or the sub-pixel SPX) that may be employed in an active matrix type display device in accordance with an embodiment. Here, the connection relationship of the components of each pixel PXL (or each sub-pixel SPX) is not limited thereto.

Referring to FIGS. 1 to 5, the sub-pixel SPX (or the pixel PXL) may include an emission component EMU configured to generate light with luminance corresponding to a data signal. Furthermore, the sub-pixel SPX may further include a pixel circuit PXC configured to drive the emission component EMU.

The emission component EMU may include a first electrode ELT1 (or a first pixel electrode) electrically connected to a first power supply VDD via the pixel circuit PXC and the first power line PL1, a fifth electrode ELT5 (or a second pixel electrode) connected to the second power supply VSS through the second power line PL2, and a plurality of light emitting elements LD which are connected between the first and fifth electrodes ELT1 and ELT2. The first driving power supply VDD and the second driving power supply VSS may have different potentials to allow the light emitting elements LD to emit light. For example, the first driving power supply VDD may be a high-potential power supply, and the second driving power supply VSS may be a low-potential power supply.

In an embodiment, the emission component EMU may include at least one series stage. Each series stage may include a pair of electrodes (e.g., two electrodes), and at least one light emitting element LD connected in a forward direction between the pair of electrodes. The number of series stage that form the emission component EMU and the number of light emitting elements LD that form each series stage are not particularly limited. For example, the numbers of light emitting elements LD that form the respective series stages may be identical to or different from each other. The number of light emitting elements LD of each series stage is not particularly limited.

For example, the emission component EMU may include a first series stage including at least one first light emitting element LD1, a second series stage including at least one second light emitting element LD2, a third series stage including at least one third light emitting element LD3, and a fourth series stage including at least one fourth light emitting element LD4.

The first series stage may include a first electrode ELT1, a second electrode ELT2 (or a first bridge electrode), and at least one first light emitting element LD1 connected between the first and second electrodes ELT1 and ELT2. Each first light emitting element LD1 may be connected in the forward direction between the first and second electrodes ELT1 and ELT2. For example, a first end EP1 of the first light emitting element LD1 may be electrically connected to the first electrode ELT1. A second end EP2 of the first light emitting element LD1 may be electrically connected to the second electrode ELT2.

The second series stage may include the second electrode ELT2, a third electrode ELT3 (or a second bridge electrode), and at least one second light emitting element LD2 connected between the second and third electrodes ELT2 and ELT3. Each second light emitting element LD2 may be connected in the forward direction between the second and third electrodes ELT2 and ELT3. For example, a first end EP1 of the second light emitting element LD2 may be electrically connected to the second electrode ELT2. A second end EP2 of the second light emitting element LD2 may be electrically connected to the third electrode ELT3.

The third series stage may include the third electrode ELT3, a fourth electrode ELT4 (or a third bridge electrode), and at least one third light emitting element LD3 connected between the third and fourth electrodes ELT3 and ELT4. Each third light emitting element LD3 may be connected in the forward direction between the third and fourth electrodes ELT3 and ELT4. For example, a first end EP1 of the third light emitting element LD3 may be electrically connected to the third electrode ELT3. A second end EP2 of the third light emitting element LD3 may be electrically connected to the fourth electrode ELT4.

The fourth series stage may include the fourth electrode ELT4, the fifth electrode ELT5, and at least one fourth light emitting element LD4 connected between the fourth and fifth electrodes ELT4 and ELT5. Each fourth light emitting element LD4 may be connected in the forward direction between the fourth and fifth electrodes ELT4 and ELT5. For example, a first end EP1 of the fourth light emitting element LD4 may be electrically connected to the fourth electrode ELT4. A second end EP2 of the fourth light emitting element LD4 may be electrically connected to the fifth electrode ELT5.

The first electrode of the emission component EMU, e.g., the first electrode ELT1, may be an anode of the emission component EMU. The last electrode of the emission component EMU, e.g., the fifth electrode ELT5, may be a cathode of the emission component EMU.

In case that the light emitting elements LD are connected to have a series/parallel structure, power efficiency may be enhanced compared to the case where the same number of light emitting elements LD are connected only in parallel to each other. Furthermore, in the sub-pixel SPX in which the light emitting elements LD are connected in a series/parallel structure, even if a short-circuit defect or the like occurs in some series stages, sufficient luminance can be expressed by the light emitting elements LD of the other series stages, so that the probability of occurrence of a black spot defect in the sub-pixel SPX can be reduced. However, the present disclosure is not limited thereto. The emission component EMU may be formed by connecting the light emitting elements LD only in series. Alternatively, the emission component EMU may be formed by connecting the light emitting elements LD only in parallel.

Each of the light emitting elements LD may include a first end EP1 (e.g., a p-type end) electrically connected to the first driving power supply VDD via at least one electrode (e.g., the first electrode ELT1), the pixel circuit PXC, the first power line PL1, and/or the like, and a second end EP2 (e.g., an n-type end) electrically connected to the second driving power supply VSS via at least one additional electrode (e.g., the fifth electrode ELT5), the second power line PL2, and the like. In other words, the light emitting elements LD may be connected in the forward direction between the first driving power supply VDD and the second driving power supply VSS. The light emitting elements LD connected in the forward direction may form valid light sources of the emission component EMU.

The light emitting elements LD may emit light with luminance corresponding to the driving current when driving current is supplied thereto through the corresponding pixel circuit PXC. For example, during each frame period, the pixel circuit PXC may supply driving current corresponding to a grayscale value to be represented in the corresponding frame to the emission component EMU. The driving current supplied to the emission component EMU may flow into the respective light emitting elements LD. Hence, each of the light emitting elements LD may emit light with luminance corresponding to current applied thereto, so that the emission component EMU may represent luminance corresponding to the driving current.

The pixel circuit PXC may be electrically connected to a scan line Si and a data line Dj of the corresponding sub-pixel SPX. For example, if the sub-pixel SPX is disposed on an i-th row and a j-th column of the display area DA, the pixel circuit PXC of the sub-pixel SPX may be electrically connected to an i-th scan line Si and a j-th data line Dj of the display area DA. Furthermore, the pixel circuit PXC may be electrically connected to an i-th control line CLi and a j-th sensing line SENj of the display area DA.

The pixel circuit PXC may include first to third transistors T1, T2, and T3, and a storage capacitor Cst.

The first transistor T1 may be a driving transistor configured to control driving current to be applied to the emission component EMU, and may be connected between the first driving power supply VDD and the emission component EMU. In detail, a first terminal of the first transistor T1 may be electrically connected to the first driving power supply VDD via the first power line PL1. A second terminal of the first transistor T1 may be electrically connected to a second node N2. A gate electrode of the first transistor T1 may be electrically connected to a first node N1. The first transistor T1 may control the amount of driving current to be applied from the first driving power supply VDD to the emission component EMU through the second node N2 in response to a voltage applied to the first node N1. In an embodiment, the first terminal of the first transistor T1 may be a drain electrode, and the second terminal of the first transistor T1 may be a source electrode.

The second transistor T2 may be a switching transistor configured to select a sub-pixel SPX in response to a scan signal and activate the sub-pixel SPX, and may be electrically connected between the j-th data line Dj and the first node N1. A first terminal of the second transistor T2 may be electrically connected to the j-th data line Dj. A second terminal of the second transistor T2 may be electrically connected to the first node N1. A gate electrode of the second transistor T2 may be electrically connected to the i-th scan line Si. The first terminal of the second transistor T2 may be a drain electrode, and the second terminal of the second transistor T2 may be a source electrode.

In case that a scan signal of a gate-on voltage (e.g., a high level voltage) is supplied from the i-th scan line Si, the second transistor T2 may be turned on to electrically connect the j-th data line Dj with the first node N1. The first node N1 may be a connection point at which the second terminal (e.g., the source electrode) of the second transistor T2 and the gate electrode of the first transistor T1 are electrically connected to each other. The second transistor T2 may transmit a data signal to the gate electrode of the first transistor T1.

The third transistor T3 may obtain a sensing signal through the sensing line SENj by electrically connecting the first transistor T1 to the j-th sensing line SENj, and detect characteristics of the sub-pixel SPX such as a threshold voltage of the first transistor T1 using the sensing signal. Information about the characteristics of each sub-pixel SPX may be used to compensate image data such that a deviation in characteristic between sub-pixels SPX can be reduced. A second terminal of the third transistor T3 may be electrically connected to the second terminal of the first transistor T1. A first terminal of the third transistor T3 may be electrically connected to the j-th sensing line SENj. A gate electrode of the third transistor T3 may be electrically connected to the i-th control line CLi. The first terminal of the third transistor T3 may be a drain electrode, and the second terminal of the third transistor T3 may be a source electrode.

The third transistor T3 may be an initialization transistor configured to initialize the second node N2, and may be turned on when a sensing control signal is supplied thereto from the i-th control line CLi, so that the voltage of the initialization power supply can be transmitted to the second node N2.

The storage capacitor Cst may include a first storage electrode (or a lower electrode) and a second storage electrode (or an upper electrode). The first storage electrode may be electrically connected to the first node N1. The second storage electrode may be electrically connected to the second node N2. The storage capacitor Cst may be charged with a data voltage corresponding to a data signal to be supplied to the first node N1 during one frame period. Hence, the storage capacitor Cst may store a voltage corresponding to a difference between a voltage of the gate electrode of the first transistor T1 and a voltage of the second node N2.

Although FIG. 5 illustrates an embodiment where all of the first to third transistors T1, T2, and T3 are N-type transistors, the present disclosure is not limited thereto. For example, at least one of the first to third transistors T1, T2, and T3 may be a P-type transistor.

The structure of the pixel circuit PXC may be changed in various ways.

In an embodiment, for the sake of explanation, a horizontal direction (or an X-axis direction) in a plan view will be designated as a first direction DR1, a vertical direction (or an Y-axis direction) in a plan view will be designated as a second direction DR2, and a vertical direction perpendicular to a plane formed by the first direction DR1 and the second direction DR2 will be designated as a third direction DR3.

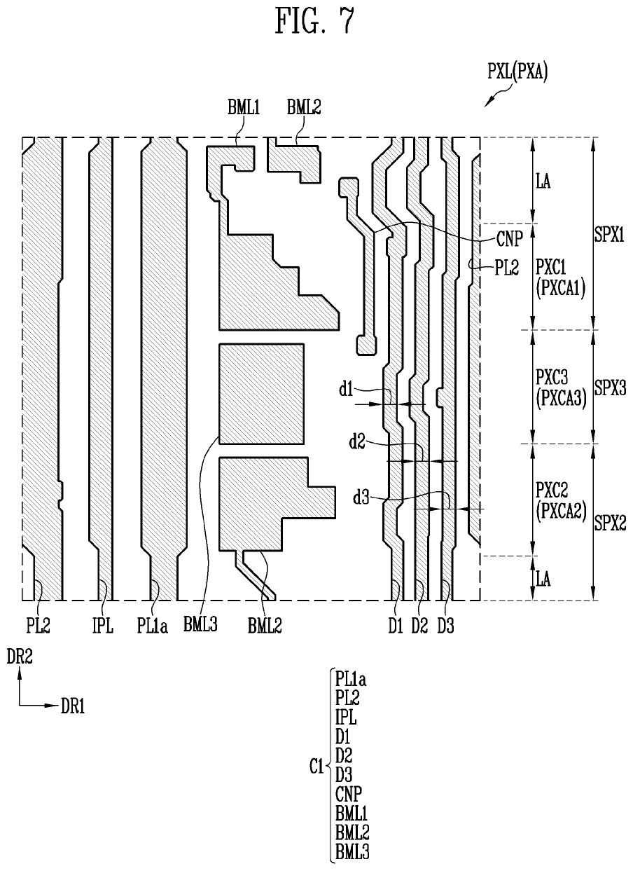

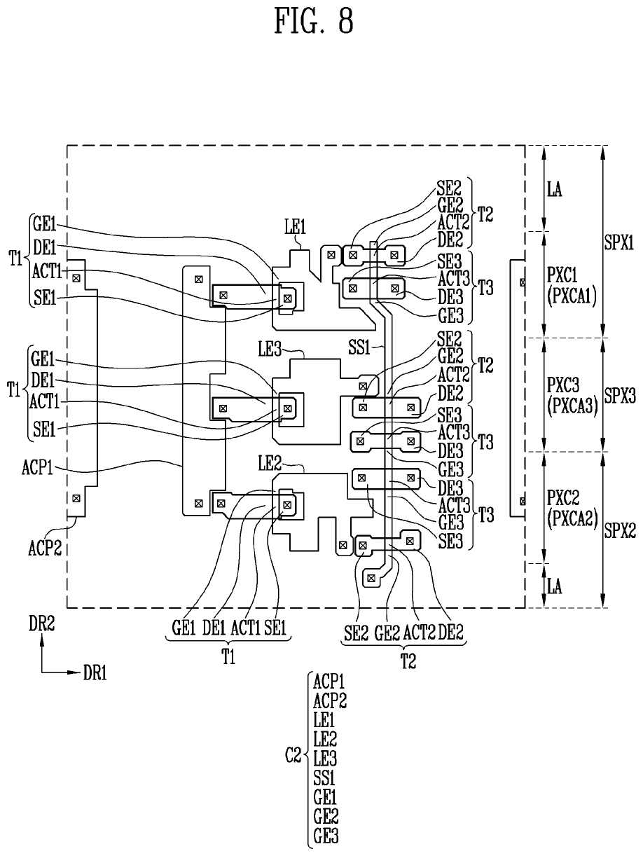

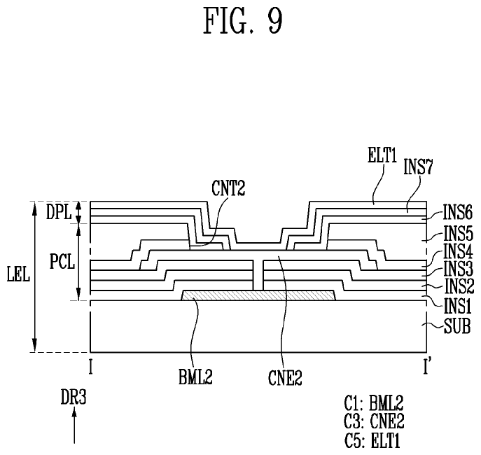

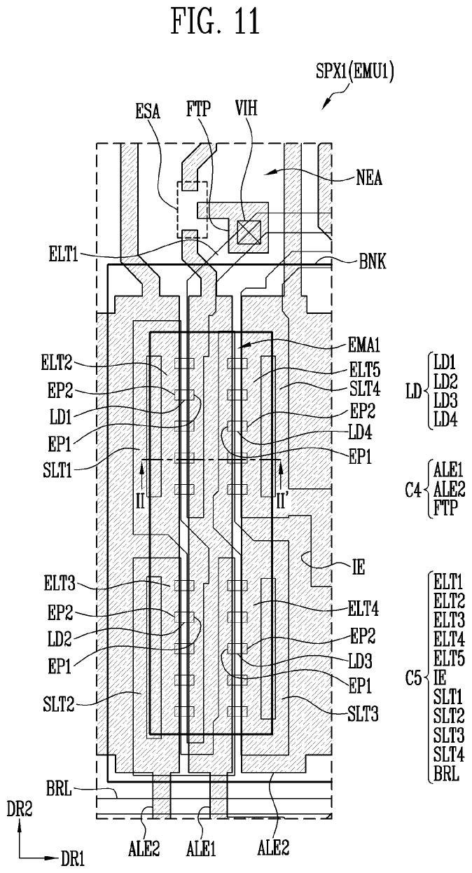

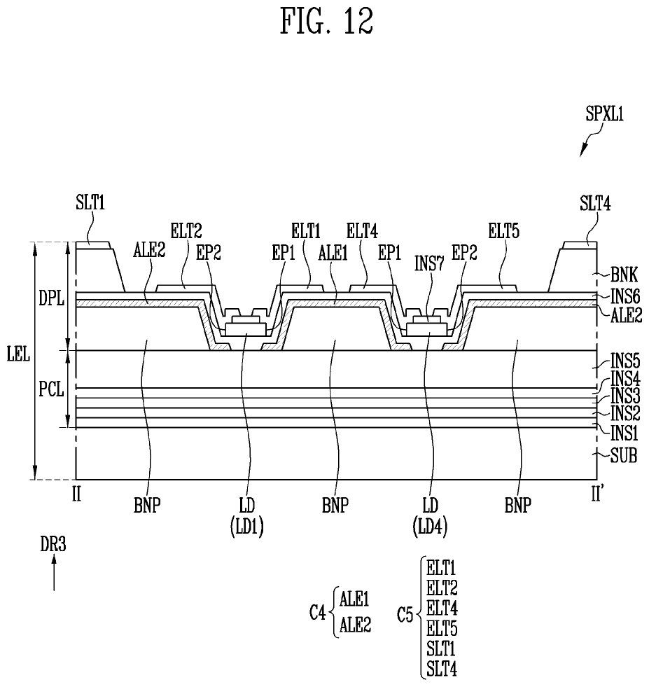

FIG. 6 is a schematic plan view illustrating the pixel circuit layer PCL of the pixel PXL in accordance with an embodiment. FIG. 7 is a schematic plan view illustrating only components included in a first conductive layer C1 in the pixel PXL of FIG. 6. FIG. 8 is a schematic plan view illustrating transistors and only components included in a second conductive layer C2 in the pixel PXL of FIG. 6. FIG. 9 is a schematic cross-sectional view taken along line I-I′ of FIG. 6. FIG. 10 is a schematic plan view illustrating the display element layer PDL of the pixel PXL in accordance with an embodiment. FIG. 11 is a schematic plan view illustrating the first sub-pixel SPX1 of FIG. 10. FIG. 12 is a schematic cross-sectional view taken along line II-II′ of FIG. 11.

In FIGS. 6 to 12, not only the components included in the pixel PXL but also an area in which the components are provided (or located) may be embraced in the definition of the term “pixel PXL”.

Referring to FIGS. 1 to 12, the pixel PXL may include a plurality of sub-pixels SPX. For example, the pixel PXL may include a first sub-pixel SPX1, a second sub-pixel SPX2, and a third sub-pixel SPX3.

The first sub-pixel SPX1 may include a first pixel circuit PXC1 and a first emission component EMU1. The second sub-pixel SPX2 may include a second pixel circuit PXC2 and a second emission component EMU2. The third sub-pixel SPX3 may include a third pixel circuit PXC3 and a third emission component EMU3.

The pixel area PXA may include a first pixel circuit area PXCA1, a third pixel circuit area PXCA3, and a second pixel circuit area PXCA2 which are disposed along the second direction DR2. The first pixel circuit area PXCA1 may be an area in which the first pixel circuit PXC1 is disposed. The second pixel circuit area PXCA2 may be an area in which the second pixel circuit PXC2 is disposed. The third pixel circuit area PXCA3 may be an area in which the third pixel circuit PXC3 is disposed.

The pixel area PXA may include a signal line area LA which is provided around each of the first and second pixel circuit areas PXCA1 and PXCA2 and/or in a portion thereof. For example, the signal line area LA may be provided at an upper side of the first pixel circuit area PXCA1 and a lower side of the second pixel circuit area PXCA2. The signal line area LA may be an area in which some signal lines extending in the first direction DR1 are disposed. For example, in the signal line area LA, there may be disposed a scan line SC and a first horizontal power line PL1b which extend in the first direction DR1.

The pixel area PXA may include a first emission area EMA1, a second emission area EMA2, and a third emission area EMA3 that are disposed along the first direction DR1.

The first emission area EMA1 may be an area where light is emitted from the light emitting elements LD that are driven by the first pixel circuit PXC1. The first emission area EMA1 may be an emission area of the first sub-pixel SPX1. The second emission area EMA2 may be an area where light is emitted from the light emitting elements LD that are driven by the second pixel circuit PXC2. The second emission area EMA2 may be an emission area of the second sub-pixel SPX2. The third emission area EMA3 may be an area where light is emitted from the light emitting elements LD that are driven by the third pixel circuit PXC3. The third emission area EMA3 may be an emission area of the third sub-pixel SPX3.

The first emission area EMA1, the second emission area EMA2, and the third emission area EMA3 may form the emission area EMA of the pixel PXL.

The pixel area PXA may include a non-emission area NEA which is disposed adjacent to each of the first emission area EMA1, the second emission area EMA2, and the third emission area EMA3 (or which encloses a periphery of each of the first emission area EMA1, the second emission area EMA2, and the third emission area EMA3).

The pixel circuit layer PCL and the display element layer DPL may be disposed on the substrate SUB in the pixel PXL (or the pixel area PXA). The pixel circuit layer PCL and the display element layer DPL may include a plurality of insulating layers. For example, the pixel circuit layer PCL may include a first insulating layer INS1, a second insulating layer INS2, a third insulating layer INS3, a fourth insulating layer INS4, and a fifth insulating layer INS5, which are successively stacked on the substrate SUB. The display element layer DPL may include a sixth insulating layer INS6 and a seventh insulating layer INS7, which are successively stacked on the pixel circuit layer PCL.

The first insulating layer INS1 (or a buffer layer) may be disposed on the overall surface of the substrate SUB. The first insulating layer INS1 may prevent impurities from diffusing into the transistors T1, T2, and T3 included in the first to third pixel circuits PXC1, PXC2, and PXC3. The first insulating layer INS1 may be an inorganic layer including inorganic material.

The first insulating layer INS1 may include at least one of silicon nitride (SiNₓ), silicon oxide (SiOₓ), silicon oxynitride (SiOₓN_{y}), and aluminum oxide (AlOₓ). Although the first insulating layer INS1 may have a single-layer structure, the first insulating layer INS1 may have a multilayer structure having at least two or more layers. The first insulating layer INS1 may be omitted depending on the material of the substrate SUB or processing conditions.

The second insulating layer INS2 (or a gate insulating layer) may be disposed on the overall surface of the first insulating layer INS1. The second insulating layer INS2 may include the same material as the first insulating layer INS1, or may include suitable (or selected) materials among materials exemplified as the constituent material of the first insulating layer INS1. For example, the second insulating layer INS2 may be formed of an inorganic layer including inorganic material.

The third insulating layer INS3 (or an interlayer insulating layer) may be disposed on the overall surface of the second insulating layer INS2. The third insulating layer INS3 may include the same material as the first insulating layer INS1, or may include one or more suitable (or selected) materials among materials exemplified as the constituent material of the first insulating layer INS1.

The fourth insulating layer INS4 (or a passivation layer) may be disposed on the overall surface of the third insulating layer INS3. The fourth insulating layer INS4 may be an inorganic layer including inorganic material or an organic layer including organic material.

The fifth insulating layer INS5 (or a via layer) may be disposed on the overall surface of the fourth insulating layer INS4. The fifth insulating layer INS5 may be an inorganic layer including inorganic material or an organic layer including organic material. The inorganic layer may include, for example, at least one of silicon oxide (SiOₓ), silicon nitride (SiNₓ), silicon oxynitride (SiOₓN_{y}), and aluminum oxide (AlOₓ). The organic layer may include, for example, at least one of polyacrylates resin, epoxy resin, phenolic resin, polyamides resin, polyimides rein, unsaturated polyesters resin, poly-phenylen ethers resin, poly-phenylene sulfides resin, and benzocyclobutene resin.

The sixth insulating layer INS6 may be disposed on the overall surface of the pixel circuit layer PCL. The sixth insulating layer INS6 may be formed of a single layer or multiple layers, and include various inorganic materials (or substances) including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The seventh insulating layer INS7 may be disposed on the sixth insulating layer INS6. The seventh insulating layer INS7 may include the same material as the sixth insulating layer INS6, or may include one or more suitable (or selected) materials among materials exemplified as the constituent material of the sixth insulating layer INS6. However, the present disclosure is not limited to the aforementioned example. For example, the seventh insulating layer INS7 may include an organic insulating layer including organic material.

The pixel PXL may include at least one or more conductive layers disposed between the above-mentioned insulating layers. For example, the conductive layers may include a first conductive layer C1 disposed on the substrate SUB, a second conductive layer C2 disposed on the second insulating layer INS2, a third conductive layer C3 disposed on the third insulating layer INS3, a fourth conductive layer C4 disposed on the fifth insulating layer INS5, and a fifth conductive layer C5 disposed on the seventh insulating layer INS7. However, the insulating layers and the conductive layers are not limited to that of those of the foregoing embodiment. In some embodiments, except the insulating layers and the conductive layers, other insulating layers and other conductive layers may be disposed on the substrate SUB. The first, second, and third conductive layers C1, C2, and C3 may be disposed on the pixel circuit layer PCL of the pixel PXL. The fourth and fifth conductive layers C4 and C5 may be disposed on the display element layer DPL of the pixel PXL.

Signal lines that are electrically connected to the pixel PXL may be formed on the substrate SUB. The signal lines may transmit certain signals (or certain voltages) to the pixel PXL. For example, the signal lines may include a scan line SC, data lines D1, D2, and D3, a power line PL, and an initialization power line IPL.

A scan signal and a sensing control signal may be selectively applied to the scan line SC. The scan line SC may extend in a first direction DR1. The scan line SC may be formed of the conductive layer C3. The third conductive layer C3 may be formed of a single layer or multiple layers made of molybdenum (Mo), copper (Cu), aluminum (Al), chrome (Cr), gold (Au), silver (Ag), titanium (Ti), nickel (Ni), neodymium (Nd), indium (In), tin (Sn), and an oxide or alloy thereof.

The scan line SC may be disposed on a sub-scan line SS1, and may be electrically connected to the sub-scan line SS1 through a contact hole. For example, the scan line SC may be electrically connected to the sub-scan line SS1 through a contact hole formed through the third insulating layer INS3.

The sub-scan line SS1 may extend in the second direction DR2. The sub-scan line SS1 may be formed of the second conductive layer C2. The second conductive layer C2 may be formed of a single-layer structure or a multi-layer structure made of molybdenum (Mo), copper (Cu), chrome (Cr), gold (Au), silver (Ag), titanium (Ti), nickel (Ni), neodymium (Nd), indium (In), tin (Sn), and an oxide or alloy thereof. For example, the second conductive layer C2 may have a multi-layer structure formed by successively or sequentially stacking titanium (Ti), copper (Cu), and/or indium tin oxide (ITO).

In an embodiment, the sub-scan line SS1 may be integrally provided with a second gate electrode GE2 of the second transistor T2 of each of the first, second, and third pixel circuits PXC1, PXC2, and PXC3. For example, a portion of the sub-scan line SS1 may be the second gate electrode GE2 of the second transistor T2 of each of the first, second, and third pixel circuits PXC1, PXC2, and PXC3. Hence, the sub-scan line SS1 may be connected to the second gate electrode GE2 of the second transistor T2 of each of the first, second, and third pixel circuits PXC1, PXC2, and PXC3.

Furthermore, the sub-scan line SS1 may be integrally provided with a third gate electrode GE3 of the third transistor T3 of each of the first, second, and third pixel circuits PXC1, PXC2, and PXC3. For example, another portion of the sub-scan line SS1 may be the third gate electrode GE3 of the third transistor T3 of each of the first, second, and third pixel circuits PXC1, PXC2, and PXC3. Hence, the sub-scan line SS1 may be connected to the third gate electrode GE3 of the third transistor T3 of each of the first, second, and third pixel circuits PXC1, PXC2, and PXC3.

As the sub-scan line SS1 is electrically connected with the first scan line S1 through a contact hole, the scan line SC may be electrically connected with some components (e.g., the second and third transistors T2 and T3) of each of the first, second, and third pixel circuits PXC1, PXC2, and PXC3 via the sub-scan line SS1. In this case, the scan line SC may supply a scan signal to the second transistor T2 of each of the first, second, and third pixel circuits PXC1, PXC2, and PXC3 during a driving period of the light emitting elements LD, and may supply a sensing control signal to the third transistor T3 of each of the first, second, and third pixel circuits PXC1, PXC2, and PXC3 during a sensing period.

The sub-scan line SS1 may be a common component provided in common to the first, second, and third pixel circuits PXC1, PXC2, and PXC3.

The data lines D1, D2, and D3 may include a first data line D1, a second data line D2, and a third data line D3 which extend in the second direction DR2 and are spaced apart from each other in the first direction DR1. Each of the first, second, and third data lines D1, D2, and D3 may be supplied with a corresponding data signal.

The first data line D1 may be electrically connected to the second transistor T2 of the first pixel circuit PXC1. The second data line D2 may be electrically connected to the second transistor T2 of the second pixel circuit PXC2. The third data line D3 may be electrically connected to the second transistor T2 of the third pixel circuit PXC3. Each of the first, second, and third data lines D1, D2, and D3 may be formed of the first conductive layer C1. The first conductive layer C1 may include the same material as that of the third conductive layer C3, or may include one or more suitable materials among materials exemplified as the constituent material of the third conductive layer C3, but the present disclosure is not limited thereto.

The first data line D1, the second data line D2, and the third data line D3 may have a similar or identical line width in the first direction DR1 at least in the pixel area PXA. For example, the first data line D1 may have a line width d1 of approximately 7 μm, the second data line D2 may have a line width d2 of approximately 7 μm, and the third data line D3 may have a line width d3 of approximately 7 μm.

The line width d1 of the first data line D1, the line width d2 of the second data line D2, and the line width d3 of the third data line D3 may be designed to be less than line widths of data lines disposed in a typical pixel. For example, the data lines disposed in the typical pixel are designed to have a line width of approximately 10.5 μm. In an embodiment, the first, second, and third data lines D1, D2, and D3 may be designed to have a line width of approximately 7 μm at least in the pixel area PXA.

The power line PL may include a first power line PL1 and a second power line PL2.

The voltage of the first driving power supply (VDD of FIG. 5) may be applied to the first power line PL1. The first power line PL1 may include a first vertical power line PL1a and a first horizontal power line PL1b which are disposed in different layers and are electrically connected to each other through a contact hole. For example, the first vertical power line PL1a may extend in the second direction DR2 and be formed of the first conductive layer C1. The first horizontal power line PL1b may extend in the first direction DR1 and be formed of the third conductive layer C3.

The first horizontal power line PL1b may include a dummy line PL1c which protrudes in the second direction DR2 and overlaps the first vertical power line PL1a. The dummy line PL1c may be formed of the third conductive layer C3. The first horizontal power line PL1b and the dummy line PL1c may be integrally formed and connected to each other. The dummy line PL1c may be electrically connected to the first vertical power line PL1a through a contact hole passing through the first insulating layer INS1, the second insulating layer INS2, and the third insulating layer INS3. The first power line PL1 may have a mesh structure because the first vertical power line PL1a and the first horizontal power line PL1b are connected to each other.

The first vertical power line PL1a and the dummy line PL1c may overlap a first additional conductive pattern ACP1 extending in the second direction DR2, and may be electrically connected to the first additional conductive pattern ACP1 through a contact hole.

The first additional conductive pattern ACP1 may be formed of the second conductive layer C2, and may be electrically connected to the dummy line PL1c through a contact hole formed through the third insulating layer INS3.

The first vertical power line PL1a may be electrically connected to the first additional conductive pattern ACP1 and the dummy line PL1c and thus implemented as a triple-layer structure. Hence, line resistance of the first vertical power line PL1a may be reduced, thus resulting in reduced signal distortion.

The first horizontal power line PL1b may be connected to a floating pattern FTP of each of the first, second, and third emission components EMU1, EMU2, and EMU3 through a via hole VIH formed through the fourth and fifth insulating layers INS4 and INS5.

The voltage of the second driving power supply (VSS of FIG. 5) may be applied to the second power line PL2. The second power line PL2 may extend in the second direction DR2. The second power line PL2 may overlap each of a second additional conductive pattern ACP2 and a seventh conductive pattern CP7 which extend in the second direction DR2. The second power line PL2 may be formed of the first conductive layer C1. The second additional conductive pattern ACP2 may be formed of the second conductive layer C2. The seventh conductive pattern CP7 may be formed of the third conductive layer C3.

Disposed in different layers, the second power line PL2, the second additional conductive pattern ACP2, and the seventh conductive pattern CP7 may be electrically connected to each other. For example, the seventh conductive pattern CP7 may be electrically connected to the second power line PL2 through a contact hole formed through the first insulating layer INS1, the second insulating layer INS2, and the third insulating layer INS3. The second additional conductive pattern ACP2 may be electrically connected to the seventh conductive pattern CP7 through a contact hole formed through the third insulating layer INS3. The second power line PL2 may be electrically connected to the second additional conductive pattern ACP2 and the seventh conductive pattern CP7 and thus implemented as a triple-layer structure. Hence, line resistance of the second power line PL2 may be reduced, thus resulting in reduced signal distortion.

The initialization power line IPL may extend in the second direction DR2. The initialization power line IPL may be the j-th sensing line SENj described with reference to FIG. 5. The voltage of the initialization power supply may be applied to the initialization power line IPL. The initialization power line IPL may be formed of the first conductive layer C1. In an embodiment, the initialization power line IPL may overlap an eighth conductive pattern CP8 extending in the second direction DR2, and may be electrically connected to the eighth conductive pattern CP8 through a contact hole.

The eighth conductive pattern CP8 may be formed of the third conductive layer C3, and may be electrically connected to the initialization power line IPL through a contact hole passing through the first, second, and third insulating layers INS1, INS2, and INS3.

The eighth conductive pattern CP8 may include a first sub-electrode SUE1 and a second sub-electrode SUE2 which extend in the first direction DR1. The first sub-electrode SUE1 and the second sub-electrode SUE2 may be integrally formed with the eighth conductive pattern CP8 formed of the third conductive layer C3. The first sub-electrode SUE1 may extend from the eighth conductive pattern CP8 along the first direction DR1 and be positioned on an upper side of the second additional conductive pattern ACP2. The second sub-electrode SUE2 may extend from the eighth conductive pattern CP8 along the first direction DR1 and be positioned on a lower side of the second additional conductive pattern ACP2.

A first end of the first sub-electrode SUE1 may extend from the eighth conductive pattern CP8 and be electrically connected to the initialization power line IPL. A second end of the first sub-electrode SUE1 may be electrically connected to a third drain electrode DE3 of the third transistor T3 of the first pixel circuit PXC1 through a contact hole formed through the second insulating layer INS2 and the third insulating layer INS3.

A first end of the second sub-electrode SUE2 may extend from the eighth conductive pattern CP8 and be electrically connected to the initialization power line IPL. A second end of the second sub-electrode SUE2 may be electrically connected to a third drain electrode DE3 of the third transistor T3 of each of the second and third pixel circuits PXC2 and PXC3 through a contact hole formed through the second insulating layer INS2 and the third insulating layer INS3.

The initialization power line IPL may be electrically connected to the eighth conductive pattern CP8 and thus implemented as a double-layer structure. Hence, line resistance of the initialization power line ILP may be reduced, thus resulting in reduced signal distortion. The first power line PL1, the second power line PL2, the initialization power line IPL, the sub-scan line SS1, the scan line SC may be common components provided in common in the first, second, and third pixel circuits PXC1, PXC2, and PXC3.

Each of the first, second, and third pixel circuits PXC1, PXC2, and PXC3 may include a first transistor T1, a second transistor T2, a third transistor T3, and a storage capacitor. For example, the first pixel circuit PXC1 may include first to third transistors T1, T2, and T3, and a first storage capacitor Cst1. The second pixel circuit PXC2 may include first to third transistors T1, T2, and T3, and a second storage capacitor Cst2. The third pixel circuit PXC3 may include first to third transistors T1, T2, and T3, and a third storage capacitor Cst3.

The first transistor T1 of each of the first to third pixel circuits PXC1, PXC2, and PXC3 may correspond to the first transistor T1 of FIG. 5. The second transistor T2 of each of the first to third pixel circuits PXC1, PXC2, and PXC3 may correspond to the second transistor T2 of FIG. 5. The third transistor T3 of each of the first to third pixel circuits PXC1, PXC2, and PXC3 may correspond to the third transistor T3 of FIG. 5.

The first to third pixel circuits PXC1, PXC2, and PXC3 may have a substantially similar or identical structure. Hereinafter, the first pixel circuit PXC1 among the first to third pixel circuits PXC1, PXC2, and PXC3 will be described as a representative example, and descriptions of the second and third pixel circuits PXC2 and PXC3 will be simplified.

The first pixel circuit PXC1 may include a first transistor T1, a second transistor T2, a third transistor T3, and a first storage capacitor Cst1.

The first transistor T1 may include a first gate electrode GE1, a first active pattern ACT1, a first source electrode SE1, and a first drain electrode DE1.

The first gate electrode GE1 may be electrically connected to a second source electrode SE2 of the second transistor T2 by a first conductive pattern CP1. The first gate electrode GE1 may be formed of the second conductive layer C2.

The first conductive pattern CP1 may be disposed in an area corresponding to the first node N1, which is a connection portion at which the first gate electrode GE1 of the first transistor T1 and the second source electrode SE2 of the second transistor T2 are electrically connected to each other, is disposed. The first conductive pattern CP1 may be formed of the third conductive layer C3. A first end of the first conductive pattern CP1 may be electrically connected to the first gate electrode GE1 through a contact hole that is formed through the third insulating layer INS3. A second end of the first conductive pattern CP1 may be electrically connected to the second source electrode SE2 through a contact hole that is formed through the second and third insulating layers INS2 and INS3. The first conductive pattern CP1 may be a bridge pattern BRP configured to electrically connect the first gate electrode GE1 of the first transistor T1 and the second source electrode SE2 of the second transistor T2 to each other. The first conductive pattern CP1 (or the bridge pattern BRP), the first gate electrode GE1 of the first transistor T1, and the second source electrode SE2 of the second transistor T2 may constitute the first node N1 of the first pixel circuit PXC1.

Each of the first active pattern ACT1, the first source electrode SE1, and the first drain electrode DE1 may be a semiconductor pattern formed of poly silicon, amorphous silicon, an oxide semiconductor, or the like. Each of the first active pattern ACT1, the first source electrode SE1, and the first drain electrode DE1 may be formed of an undoped semiconductor layer or a semiconductor layer doped with an impurity. For example, each of the first source electrode SE1 and the first drain electrode DE1 may be formed of a semiconductor layer doped with an impurity. The first active pattern ACT1 may be formed of an undoped semiconductor layer.

The first active pattern ACT1, the first source electrode SE1, and the first drain electrode DE1 may be disposed on the first insulating layer INS1.

The first active pattern ACT1 may be a channel area of the first transistor T1 which is overlapped with the first gate electrode GE1.

The first source electrode SE1 may be connected to a first end of the first active pattern ACT1. The first source electrode SE1 may be electrically connected to a first upper electrode UE1 through a contact hole that is formed through the second and third insulating layers INS2 and INS3.

The first drain electrode DE1 may be connected to a second end of the first active pattern ACT1. The first drain electrode DE1 may be electrically connected to the dummy line PL1c of the first horizontal power line PL1b through a contact hole that is formed through the second and third insulating layers INS2 and INS3.

The second transistor T2 may include a second gate electrode GE2, a second active pattern ACT2, a second source electrode SE2, and a second drain electrode DE2.

The second gate electrode GE2 may be formed of the second conductive layer C2. The second gate electrode GE2 may be integrally formed with the sub-scan line SS1 and correspond to a certain area of the sub-scan line SS1. As the sub-scan line SS1 is electrically connected with the scan line SC through a contact hole, a certain signal (e.g., a scan signal) applied to the scan line SC may be applied to the second gate electrode GE2.

Each of the second active pattern ACT2, the second source area SE2, and the second drain area DE2 may be a semiconductor pattern formed of amorphous silicon, an oxide semiconductor, or the like. Each of the second active pattern ACT2, the second source electrode SE2, and the second drain electrode DE2 may be formed of an undoped semiconductor layer or a semiconductor layer doped with an impurity. For example, each of the second source electrode SE2 and the second drain electrode DE2 may be formed of a semiconductor layer doped with an impurity. The second active pattern ACT2 may be formed of an undoped semiconductor layer. The second active pattern ACT2, the second source area SE2, and the second drain area DE2 may be provided and/or formed on the first insulating layer INS1.

The second active pattern ACT2 may be a channel area of the second transistor T2 which is overlapped with the second gate electrode GE2.

The second source electrode SE2 may be connected to a first end of the second active pattern ACT2. The second source area SE2 may be electrically connected to the first gate electrode GE1 by the first conductive pattern CP1.

The second drain electrode DE2 may be connected to a second end of the second active pattern ACT2. The second drain electrode DE2 may be electrically connected to the first data line D1 by a second conductive pattern CP2.

The second conductive pattern CP2 may be formed of the third conductive layer C3. A first end of the second conductive pattern CP2 may be electrically connected to the first data line D1 through a contact hole that is formed through the first, second, and third insulating layers INS1, INS2, and INS3. A second end of the second conductive pattern CP2 may be electrically connected to the second drain electrode DE2 through a contact hole that is formed through the second and third insulating layers INS2 and INS3. The second drain electrode DE2 and the first data line D1 may be electrically connected to each other by the second conductive pattern CP2.

The third transistor T3 may include a third gate electrode GE3, a third active pattern ACT3, a third source electrode SE3, and a third drain electrode DE3.

The third gate electrode GE3 may be formed of the second conductive layer C2. The third gate electrode GE3 may be integrally formed with the sub-scan line SS1 and correspond to another certain area of the sub-scan line SS1. As the sub-scan line SS1 is connected with the scan line SC through a contact hole, a certain signal (e.g., a sensing control signal) applied to the scan line SC may be ultimately supplied to the third gate electrode GE3.

The third active pattern ACT3, the third source electrode SE3, and the third drain electrode DE3 each may be a semiconductor pattern formed of poly silicon, amorphous silicon, an oxide semiconductor, or the like. Each of the third active pattern ACT3, the third source electrode SE3, and the third drain electrode DE3 may be formed of an undoped semiconductor layer or a semiconductor layer doped with an impurity. For example, each of the third source electrode SE3 and the third drain electrode DE3 may be formed of a semiconductor layer doped with an impurity. The third active pattern ACT3 may be formed of an undoped semiconductor layer.

The third active pattern ACT3, the third source electrode SE3, and the third drain electrode DE3 may be disposed on the first insulating layer INS1.

The third active pattern ACT3 may correspond to a channel area of the third transistor T3 which is overlapped with the third gate electrode GE3.

The third source electrode SE3 may be connected to a first end of the third active pattern ACT3. The third source electrode SE3 may be electrically connected to the first upper electrode UE1 through a contact hole that is formed through the second and third insulating layers INS2 and INS3.

The third drain electrode DE3 may be connected to a second end of the third active pattern ACT3. The third drain electrode DE3 may be electrically connected to the first sub-electrode SUE1 through a corresponding contact hole.

The first storage capacitor Cst1 may include a first lower electrode LE1 and the first upper electrode UE1. The first storage capacitor Cst1 may correspond to the storage capacitor Cst of FIG. 5.

The first lower electrode LE1 may be integrally provided with the first gate electrode GE1. In this case, the first lower electrode LE1 may be a certain area of the first gate electrode GE1. The first lower electrode LE1 may be formed of the second conductive layer C2.

A first bottom metal pattern BML1 may be disposed under the first lower electrode LE1. The first bottom metal pattern BML1 and the first lower electrode LE1 may overlap each other.

The first bottom metal pattern BML1 may be formed of the first conductive layer C1. The first bottom metal pattern BML1 may be electrically connected to the first upper electrode UE1 through a contact hole that is formed through the first, second, and third insulating layers INS1, INS2, and INS3. The first bottom metal pattern BML1 may be electrically connected to a first contact electrode CNE1 through another contact hole that is formed through the first, second, and third insulating layers INS1, INS2, and INS3.

The first contact electrode CNE1 may be formed of the third conductive layer C3. The first contact electrode CNE1 may be electrically connected with the first bottom metal pattern BML1 through a contact hole. The first contact electrode CNE1 may be electrically connected to the first electrode ELT1 of the first emission component EMU1 through a first contactor CNT1 that is formed through the fourth, fifth, sixth, and seventh insulating layers INS4, INS5, INS6, and INS7.

The first upper electrode UE1 may be disposed to overlap the first lower electrode LE1 in a plan view, and have a size (or a surface area) greater than that of the first lower electrode LE1, but the present disclosure is not limited thereto. In a plan view, the first upper electrode UE1 may overlap each of the first source electrode SE1 and the third source electrode SE3. The first upper electrode UE1 may be formed of the third conductive layer C3.

The first upper electrode UE1 may be electrically connected to the first bottom metal pattern BML1 through a contact hole that is formed through the first, second, and third insulating layers INS1, INS2, and INS3. Furthermore, the first upper electrode UE1 may be electrically connected to the first source electrode SE1 through a contact hole that is formed through the second and third insulating layers INS2 and INS3. Furthermore, the first upper electrode UE1 may be electrically connected to the third source electrode SE3 through another contact hole that is formed through the second and third insulating layers INS2 and INS3. The first upper electrode UE1, the first bottom metal pattern BML1, the first source electrode SE1, and the third source electrode SE3 may be electrically connected to each other.

The second pixel circuit PXC2 may include a first transistor T1, a second transistor T2, a third transistor T3, and a second storage capacitor Cst2.

The first transistor T1 may include a first gate electrode GE1, a first active pattern ACT1, a first source electrode SE1, and a first drain electrode DE1.

The first gate electrode GE1 may be electrically connected to a second source electrode SE2 of the second transistor T2.

The first active pattern ACT1 may be a channel area of the first transistor T1.

The first source electrode SE1 may be connected to the first active pattern ACT1. The first source electrode SE1 may be electrically connected to a second upper electrode UE2 through a contact hole that is formed through the second and third insulating layers INS2 and INS3.

The first drain electrode DE1 may be connected to the first active pattern ACT1. The first drain electrode DE1 may be electrically connected to the dummy line PL1c of the first horizontal power line PL1b through a contact hole that is formed through the second and third insulating layers INS2 and INS3.

The second transistor T2 may include a second gate electrode GE2, a second active pattern ACT2, a second source electrode SE2, and a second drain electrode DE2.

The second gate electrode GE2 may be integrally provided with the sub-scan line SS1 and be electrically connected with the scan line SC. The second gate electrode GE2 may be formed of the second conductive layer C2.

The second active pattern ACT2 may be a channel area of the second transistor T2.

The second source electrode SE2 may be connected to the second active pattern ACT2. The second source area SE2 may be electrically connected to the first gate electrode GE1 by the third conductive pattern CP3.

The third conductive pattern CP3 may be disposed in an area corresponding to the first node N1, which is a connection portion at which the first gate electrode GE1 of the first transistor T1 and the second source electrode SE2 of the second transistor T2 are electrically connected to each other. The third conductive pattern CP3 may be formed of the third conductive layer C3. A first end of the third conductive pattern CP3 may be electrically connected to the second source electrode SE2 through a contact hole that is formed through the second and third insulating layers INS2 and INS3. A second end of the third conductive pattern CP3 may be electrically connected to the first gate electrode GE1 through a contact hole that is formed through the third insulating layer INS3. The third conductive pattern CP3 may be a bridge pattern BRP configured to electrically connect the first gate electrode GE1 of the first transistor T1 and the second source electrode SE2 of the second transistor T2 to each other. The third conductive pattern CP3 (or the bridge pattern BRP), the first gate electrode GE1 of the first transistor T1, and the second source electrode SE2 of the second transistor T2 may constitute the first node N1 of the second pixel circuit PXC2.

The second drain electrode DE2 may be connected to the second active pattern ACT2. The second drain electrode DE2 may be electrically connected to the second data line D2 by the fourth conductive pattern CP4.

The fourth conductive pattern CP4 may be formed of the third conductive layer C3. A first end of the fourth conductive pattern CP4 may be electrically connected to the second data line D2 through a contact hole that is formed through the first, second, and third insulating layers INS1, INS2, and INS3. A second end of the fourth conductive pattern CP4 may be electrically connected to the second drain electrode DE2 through a contact hole that is formed through the second and third insulating layers INS2 and INS3. The second drain electrode DE2 and the second data line D2 may be electrically connected to each other by the fourth conductive pattern CP4.

The third transistor T3 may include a third gate electrode GE3, a third active pattern ACT3, a third source electrode SE3, and a third drain electrode DE3.

The third gate electrode GE3 may be formed of the second conductive layer C2. The third gate electrode GE3 may be integrally formed with the sub-scan line SS1 and be electrically connected with the scan line SC.

The third active pattern ACT3 may be a channel area of the third transistor T3.

The third source electrode SE3 may be connected to the third active pattern ACT3. The third source electrode SE3 may be electrically connected to the second upper electrode UE2 through a contact hole that is formed through the second and third insulating layers INS2 and INS3.

The third drain electrode DE3 may be coupled to the third active pattern ACT3. The third drain electrode DE3 may be electrically connected to the second sub-electrode SUE2 through a corresponding contact hole.

The second storage capacitor Cst2 may include a second lower electrode LE2 and a second upper electrode UE2. The second storage capacitor Cst2 may correspond to the storage capacitor Cst of FIG. 5.

The second lower electrode LE2 may be integrally formed with the first gate electrode GE1. In this case, the second lower electrode LE2 may be a certain area of the first gate electrode GE1. The second lower electrode LE2 may be formed of the second conductive layer C2.

A second bottom metal pattern BML2 may be disposed under the second lower electrode LE2. The second bottom metal pattern BML2 and the second lower electrode LE2 may overlap each other.

The second bottom metal pattern BML2 may be formed of the first conductive layer C1. The second bottom metal pattern BML2 may be electrically connected to the second upper electrode UE2 through a contact hole that is formed through the first, second, and third insulating layers INS1, INS2, and INS3. The second bottom metal pattern BML2 may be electrically connected to a second contact electrode CNE2 through another contact hole that is formed through the first, second, and third insulating layers INS1, INS2, and INS3.

The second contact electrode CNE2 may be formed of the third conductive layer C3. The second contact electrode CNE2 may be electrically connected with the second bottom metal pattern BML2 through a contact hole. The second contact electrode CNE2 may be electrically connected to the first electrode ELT1 of the second emission component EMU2 through a second contactor CNT2 that is formed through the fourth, fifth, sixth, and seventh insulating layers INS4, INS5, INS6, and INS7.

The second upper electrode UE2 may be disposed to overlap the second lower electrode LE2 in a plan view, and have a size (or a surface area) greater than that of the second lower electrode LE2, but the present disclosure is not limited thereto. In a plan view, the second upper electrode UE2 may overlap each of the first source electrode SE1 and the third source electrode SE3. The second upper electrode UE2 may be formed of the third conductive layer C3.

The second upper electrode UE2, the second bottom metal pattern BML2, the first source electrode SE1, and the third source electrode SE3 may be electrically connected to each other.

The third pixel circuit PXC3 may include a first transistor T1, a second transistor T2, a third transistor T3, and a third storage capacitor Cst3.

The first transistor T1 may include a first gate electrode GE1, a first active pattern ACT1, a first source electrode SE1, and a first drain electrode DE1.

The first gate electrode GE1 may be electrically connected to a second source electrode SE2 of the second transistor T2.

The first active pattern ACT1 may be a channel area of the first transistor T1.

The first source electrode SE1 may be connected to the first active pattern ACT1. The first source electrode SE1 may be electrically connected to a third upper electrode UE3 through a contact hole that is formed through the second and third insulating layers INS2 and INS3.

The first drain electrode DE1 may be connected to the first active pattern ACT1. The first drain electrode DE1 may be electrically connected to the dummy line PL1c of the first horizontal power line PL1b through a contact hole that is formed through the second and third insulating layers INS2 and INS3.

The second transistor T2 may include a second gate electrode GE2, a second active pattern ACT2, a second source electrode SE2, and a second drain electrode DE2.

The second gate electrode GE2 may be integrally provided with the sub-scan line SS1 and be electrically connected with the scan line SC. The second gate electrode GE2 may be formed of the second conductive layer C2.

The second active pattern ACT2 may be a channel area of the second transistor T2.

The second source electrode SE2 may be connected to the second active pattern ACT2. The second source area SE2 may be electrically connected to the first gate electrode GE1 by the fifth conductive pattern CP5.

The fifth conductive pattern CP5 may be disposed in an area corresponding to the first node N1, which is a connection portion at which the first gate electrode GE1 of the first transistor T1 and the second source electrode SE2 of the second transistor T2 are electrically connected to each other. The fifth conductive pattern CP5 may be formed of the third conductive layer C3. A first end of the fifth conductive pattern CP5 may be electrically connected to the first gate electrode GE1 through a contact hole that is formed through the third insulating layer INS3. A second end of the fifth conductive pattern CP5 may be electrically connected to the second source electrode SE2 through a contact hole that is formed through the second and third insulating layers INS2 and INS3. The fifth conductive pattern CP5 may be a bridge pattern BRP configured to electrically connect the first gate electrode GE1 of the first transistor T1 and the second source electrode SE2 of the second transistor T2 to each other. The fifth conductive pattern CP5 (or the bridge pattern BRP), the first gate electrode GE of the first transistor T1, and the second source electrode SE2 of the second transistor T2 may constitute the first node N1 of the third pixel circuit PXC3.

The second drain electrode DE2 may be connected to the second active pattern ACT2. The second drain electrode DE2 may be electrically connected to the third data line D3 by a sixth conductive pattern CP6.

The sixth conductive pattern CP6 may be formed of the third conductive layer C3. A first end of the sixth conductive pattern CP6 may be electrically connected to the third data line D3 through a contact hole that is formed through the first, second, and third insulating layers INS1, INS2, and INS3. A second end of the sixth conductive pattern CP6 may be electrically connected to the second drain electrode DE2 through a contact hole that is formed through the second and third insulating layers INS2 and INS3. The second drain electrode DE2 and the third data line D3 may be electrically connected to each other by the sixth conductive pattern CP6.

The third transistor T3 may include a third gate electrode GE3, a third active pattern ACT3, a third source electrode SE3, and a third drain electrode DE3.

The third gate electrode GE3 may be formed of the second conductive layer C2. The third gate electrode GE3 may be integrally formed with the sub-scan line SS1 and be electrically connected with the scan line SC.

The third active pattern ACT3 may be a channel area of the third transistor T3.

The third source electrode SE3 may be connected to the third active pattern ACT3. The third source electrode SE3 may be electrically connected to the third upper electrode UE3 through a contact hole that is formed through the second and third insulating layers INS2 and INS3.

The third drain electrode DE3 may be coupled to the third active pattern ACT3. The third drain electrode DE3 may be electrically connected to the second sub-electrode SUE2 through a corresponding contact hole.

The third storage capacitor Cst3 may include a third lower electrode LE3 and a third upper electrode UE3. The third storage capacitor Cst3 may correspond to the storage capacitor Cst of FIG. 5.

The third lower electrode LE3 may be integrally formed with the first gate electrode GE1. In this case, the third lower electrode LE3 may be a certain area of the first gate electrode GE1. The third lower electrode LE3 may be formed of the second conductive layer C2.

A third bottom metal pattern BML3 may be disposed under the third lower electrode LE3. The third bottom metal pattern BML3 and the third lower electrode LE3 may overlap each other.

The third bottom metal pattern BML3 may be formed of the first conductive layer C1. The third bottom metal pattern BML3 may be electrically connected to the third upper electrode UE3 through a contact hole that is formed through the first, second, and third insulating layers INS1, INS2, and INS3.

The third upper electrode UE3 may be disposed to overlap the third lower electrode LE3 in a plan view, and have a size (or a surface area) greater than that of the third lower electrode LE3, but the present disclosure is not limited thereto. In a plan view, the third upper electrode UE3 may overlap each of the first source electrode SE1 and the third source electrode SE3. The third upper electrode UE3 may be formed of the third conductive layer C3.

The third upper electrode UE3, the third bottom metal pattern BML3, the first source electrode SE1, and the third source electrode SE3 may be electrically connected to each other.

In an embodiment, the third upper electrode UE3 may be electrically connected to a connection pattern CNP through a contact hole that is formed through the first, second, and third insulating layers INS1, INS2, and INS3.

The connection pattern CNP may be formed of the first conductive layer C1. A first end of the connection pattern CNP may be electrically connected to the third upper electrode UE3 through a contact hole. A second end of the connection pattern CNP may be electrically connected to a third contact electrode CNE3 through a contact hole that is formed through the first, second, and third insulating layers INS1, INS2, and INS3.

The third contact electrode CNE3 may be formed of the third conductive layer C3. The third contact electrode CNE3 may be electrically connected to the connection pattern CNP through a contact hole. The third contact electrode CNE3 may be electrically connected to the first electrode ELT1 of the third emission component EMU3 through a third contactor CNT3 that is formed through the fourth, fifth, sixth, and seventh insulating layers INS4, INS5, INS6, and INS7.

Each of the first, second, and third pixel circuits PXC1, PXC2, and PXC3 may be electrically connected to the corresponding emission component through the contactor CNT and the contact electrode CNE.

The first emission component EMU1 may be electrically connected to the first contact electrode CNE1 through the first contactor CNT1. The first contact electrode CNE1 may be electrically connected to the first bottom metal pattern BML1 through a contact hole. The first bottom metal pattern BML1 may be electrically connected to the first upper electrode UE1 of the first pixel circuit PXC1 through a contact hole. The first electrode ELT1 (or the first pixel electrode) of the first mission component EMU1 may be electrically connected to the first contact electrode CNE1 through the first contactor CNT1 and thus electrically connected to the first upper electrode UE1 of the first pixel circuit PXC1 that is electrically connected to the first contact electrode CNE1.

The second emission component EMU2 may be electrically connected to the second contact electrode CNE2 through the second contactor CNT2. The second contact electrode CNE2 may be electrically connected to the second bottom metal pattern BML2 through a contact hole. The second bottom metal pattern BML2 may be electrically connected to the second upper electrode UE2 of the second pixel circuit PXC2 through a contact hole. The first electrode ELT1 (or the first pixel electrode) of the second mission component EMU2 may be electrically connected to the second contact electrode CNE2 through the second contactor CNT2 and thus electrically connected to the second upper electrode UE2 of the second pixel circuit PXC2 that is electrically connected to the second contact electrode CNE2.

The third emission component EMU3 may be electrically connected to the third contact electrode CNE3 through the third contactor CNT3. The third contact electrode CNE3 may be electrically connected to the connection pattern CNP through a contact hole. The third connection pattern CNP may be electrically connected to the third upper electrode UE3 of the third pixel circuit PXC3 through a contact hole. The first electrode ELT1 (or the first pixel electrode) of the third mission component EMU3 may be electrically connected to the third contact electrode CNE3 through the third contactor CNT3 and thus electrically connected to the third upper electrode UE3 of the third pixel circuit PXC3 that is electrically connected to the third contact electrode CNE3.

Each of the first, second, and third contact electrodes CNE1, CNE2, and CNE3 may be formed of the third conductive layer C3, and may be disposed on the third insulating layer INS3. Each of The first, second, and third contact electrodes CNE1, CNE2, and CNE3 may have a multilayer structure formed by successively or sequentially stacking, e.g., titanium, copper, and/or indium tin oxide. In this case, because contact resistance attributable to an oxide layer (e.g., an aluminum oxide layer) may be improved, an issue of heat generation from the contactor CNT and a reduction in luminance of the display device DD can be mitigated.

The first, second, and third contactors CNT1, CNT2, and CNT3 may have a substantially similar or identical structure. Hereinafter, the second contactor CNT2 among the first, second, and third contactors CNT1, CNT2, and CNT3 will be described as a representative example with reference to FIG. 9, and the description of the first and third contactors CNT1 and CNT3 will be simplified.

The fourth insulating layer INS4 may be disposed on the second contact electrode CNE2. The fourth insulating layer INS4 may include the second contactor CNT2 formed by removing a certain area thereof at least in the emission area EMA to allow a certain area of the second contact electrode CNE2 to be exposed. The fifth insulating layer INS5 may be disposed on the fourth insulating layer INS4. The fifth insulating layer INS5 may have a certain area removed to allow a certain area of the second contact electrode CNE2 to be exposed. The sixth insulating layer INS6 may be disposed on the fifth insulating layer INS5. The sixth insulating layer INS6 may have a certain area removed to allow a certain area of the second contact electrode CNE2 to be exposed. The seventh insulating layer INS7 may be disposed on the sixth insulating layer INS6. The seventh insulating layer INS7 may have a certain area removed to allow a certain area of the second contact electrode CNE2 to be exposed.

The first electrode ELT1 may be disposed on the seventh insulating layer INS7. The first electrode ELT1 may directly contact the second contact electrode CNE2 exposed through the second contactor CNT2. In the case where the second contact electrode CNE2 of the second pixel circuit PXC2 formed of the third conductive layer C3 (or a source-drain conductive layer) directly contacts the first electrode ELT1 of the second emission component EMU2 formed of the fifth conductive layer C5, the contact resistance may be minimized, so that a heat generation issue and a luminance degradation problem of the display device DD can be mitigated.

Hereinafter, the emission component of the pixel PXL will be described in detail with reference to FIGS. 10 to 12. The pixel PXL may include a first emission component EMU1, a second emission component EMU2, and a third emission component EMU3, which are positioned in the display element layer DPL.

Each of the first, second, and third emission components EMU1, EMU2, and EMU3 may include light emitting elements LD electrically connected to a corresponding pixel circuit to emit light, and electrodes (or electrode patterns) electrically connected to the light emitting elements LD.

The display element layer DPL may include a bank BNK disposed in the non-emission area NEA.

The bank BNK may be a pixel defining layer as a structure which defines (or partitions) the first, second, and third emission areas EMA1, EMA2, and EMA3. The bank BNK may define a position of light emitting elements LD during a process of forming (or inputting) the light emitting elements LD to each sub-pixel SPX. For example, because the emission area of each sub-pixel SPX is defined by the bank BNK, a mixed solution (e.g., ink) including a target amount and/or type of light emitting elements LD may be formed (or inputted) to the corresponding emission area.

In an embodiment, the bank BNK may include at least one light blocking material and/or reflective material (or scattering material), thus preventing a light leakage defect in which light leaks between adjacent sub-pixels SPX. In an embodiment, the bank BNK may include transparent material (or substance). The transparent material may include, for example, polyamides resin, polyimides resin, and the like, but the present disclosure is not limited thereto. In an embodiment, in order to enhance the efficiency of light emitted from each sub-pixel SPX, a separate reflective material layer may be provided and/or formed on the bank BNK.

The bank BNK may include opening areas which expose components disposed thereunder in the pixel area PXA. The first, second, and third emission areas EMA1, EMA2, and EMA3 may be respectively defined by the opening areas of the bank BNK. The first to third emission areas EMA1, EMA2, and EMA3 may respectively correspond to the opening areas of the bank BNK.

Because the bank BNK is disposed in the non-emission area NEA between the first to third emission areas EMA1, EMA2, and EMA3, an (or input) area to which light emitting elements LD are to be disposed (or input) may be determined. Hence, at the step of forming light emitting elements LD to the pixel PXL, the light emitting elements LD may be prevented from being formed to undesired areas, and the light emitting elements LD may be efficiently formed to each of the first to third emission areas EMA1, EMA2, and EMA3.

An electrode separation area ESA may be disposed in the non-emission area NEA of each sub-pixel SPX. The electrode separation area ESA may be an area in which a first alignment electrode ALE1 in each sub-pixel SPX is separated from first alignment electrodes ALE1 positioned in sub-pixels SPX arranged in the same pixel column.

Each of the first, second, and third emission components EMU1, EMU2, and EMU3 may include electrodes ELT, light emitting elements LD which are electrically connected to the electrodes ELT, and alignment electrodes ALE disposed at positions corresponding to the electrodes ELT. In each of the first, second, and third emission components EMU1, EMU2, and EMU3, there may be disposed a first electrode ELT1 (or a first pixel electrode), a second electrode ELT2 (or a first bridge electrode), a third electrode ELT3 (or a second bridge electrode), a fourth electrode ELT4 (or a third bridge electrode), a fifth electrode ELT5 (or a second pixel electrode), light emitting elements LD, and first and second alignment electrodes ALE1 and ALE2. The electrodes ELT and/or the alignment electrodes ALE each may be changed in number, shape, size, arrangement structure, etc. in various ways depending on the structure of the first, second, and third emission components EMU1, EMU2, and EMU3.

Based on one surface of the substrate SUB on which the first, second, and third sub-pixels SPX1, SPX2, and SPX3 are positioned, the alignment electrodes ALE, the light emitting elements LD, and the electrodes ELT may be provided in the order listed, but the present disclosure is not limited thereto.

The alignment electrodes ALE may include the first alignment electrode ALE1 and the second alignment electrode ALE2 which are spaced apart from each other in the first direction DR1. The first and second alignment electrodes ALE1 and ALE2 may extend in the second direction DR2. In at least each of the first, second, and third emission areas EMA1, EMA2, EMA3, the first and second alignment electrodes ALE1 and ALE2 may be arranged in a sequence of the second alignment electrode ALE2, the first alignment electrode ALE1, and the second alignment electrode ALE2 in the first direction DR1.

The first alignment electrode ALE1 may be separated from the floating pattern FTP after the light emitting elements LD are supplied and aligned in each of the first, second, and third emission areas EMA1, EMA2, and EMA3. In detail, before the light emitting elements LD are aligned in each of the first, second, and third emission areas EMA1, EMA2, and EMA3, the first alignment electrode ALE1 may be integrally formed with the floating pattern FTP to form a first alignment line for aligning the light emitting elements LD. The floating pattern FTP may be electrically connected to the first horizontal power line PL1b of the pixel circuit layer PCL through a via hole VIH. The first alignment electrode ALE and the floating pattern FTP may be formed of the fourth conductive layer C4. After a process of aligning the light emitting elements LD has been completed, the first alignment line may be cut off in the electrode separation area ESA disposed close to the floating pattern FTP, so that first alignment line may be divided into first alignment electrodes ALE1 and floating patterns FTP. Furthermore, the first alignment line may be cut off in the electrode separation area ESA between adjacent pixel columns, so that the first alignment electrodes ALE1 of adjacent sub-pixels SPX can be separated from each other. After the alignment of the light emitting elements LD, the first alignment electrode ALE1 may be electrically insulated from other electrodes, and thus float.

Regardless of whether the light emitting elements LD are aligned before or after, the second alignment electrode ALE2 may be electrically connected to the second power line PL2 of the pixel circuit layer PCL. Hence, the second alignment electrode ALE2 may be supplied with an alignment signal from the second power line PL2 before the alignment of the light emitting elements LD, and may be supplied with a voltage of the second driving power supply VSS from the second power line PL2 after the alignment of the light emitting elements LD. The second alignment electrode ALE2 may be formed of the fourth conductive layer C4.

Bank patterns BNP may be disposed under the first alignment electrode ALE1 and the second alignment electrode ALE2 to change the surface profiles (or the shapes) of the first and second alignment electrodes ALE1 and ALE2 such that light emitted from the light emitting elements LD is guided in an image display direction of the display device DD. The bank patterns BNP may be support components for respectively supporting the first and second alignment electrodes ALE1 and ALE2.

The bank patterns BNP may be disposed on the fifth insulating layer INS5 of the pixel circuit layer PCL. The bank patterns BNP each may be formed of a separate pattern that is individually disposed under each of the first and second alignment electrodes ALE1 and ALE2 such that the separate pattern overlaps a portion of a corresponding one of the first and second alignment electrodes ALE1 and ALE2. In an embodiment, the bank patterns BNP may be formed of an integrated pattern that has openings or recesses corresponding to areas between the first and second alignment electrodes ALE1 and ALE2 in each of the first, second, and third emission areas EMA1, EMA2, and EMA3 and is generally integrally formed in the display area DA.

Because the bank patterns BNP are provided under respective certain areas of the alignment electrodes ALE, the respective certain areas of the alignment electrodes ALE may protrude in an upward direction of the pixel PXL, i.e., in the third direction DR3, in the areas where the respective bank patterns BNP are formed.

The bank patterns BNP each may be an inorganic insulating layer including inorganic material or an organic insulating layer including organic material. However, the material of the bank patterns BNP is not limited to the foregoing embodiment. In an embodiment, the bank patterns BNP may include conductive material (or conductive substance). The shape of the bank patterns BNP may be changed in various ways within a range in which efficiency of light emitted from the light emitting element LD can be enhanced.

The first alignment electrode ALE1 and the second alignment electrode ALE2 each may be formed of material having a reflectivity (or a certain reflectivity) to allow light emitted from the light emitting elements LD to travel in an image display direction of the display device DD. For example, the first alignment electrode ALE1 and the second alignment electrode ALE2 may be formed of conductive material (or substance). The conductive material may include opaque metal that is suitable for reflecting light emitted from the light emitting elements LD in the image display direction (or an upward direction of the display element layer DPL) of the display device DD, but is not limited thereto.

Each of the first alignment electrode ALE1 and the second alignment electrode ALE2 may be provided and/or formed in the form of a single layer structure, but is not limited thereto. In an embodiment, the first alignment electrode ALE1 and the second alignment electrode ALE2 each may be provided and/or formed to have a multilayer structure formed by stacking at least two materials among metals, alloys, conductive oxide, and conductive polymers.

In case that the bank patterns BNP and/or the alignment electrodes ALE include reflective material, a reflective wall structure may be formed around the light emitting elements LD. Hence, light emitted from the light emitting elements LD may be emitted in the upward direction of each sub-pixel SPX (e.g., in a frontal direction of the display panel DP including a predetermined viewing angle range), so that the light output efficiency of the display device DD (or the display panel DP) may be improved.

Hereinafter, the configuration of the first sub-pixel SPX1 will be described based on FIGS. 11 and 12. For the convenience sake, repetitive explanation of the same configuration as that described above will be omitted.

The light emitting elements LD may be disposed and/or aligned in the first emission area EMA1 of the first sub-pixel SPX1.

The light emitting elements LD may be disposed between the first alignment electrode ALE1 and the second alignment electrode ALE2. In a plan view, each of the light emitting elements LD may include a first end EP1 and a second end EP2 which are positioned (or face each other) on respective opposite ends of the light emitting element LD in the longitudinal direction thereof, e.g., in the first direction DR1. The second semiconductor layer (reference numeral 13 in FIG. 1) including a p-type semiconductor layer may be disposed on the first end EP1 (or the p-type end), and the first semiconductor layer (reference numeral 11 in FIG. 1) including an n-type semiconductor layer may be disposed on the second end EP2 (or the n-type end).

The light emitting elements LD may be formed in the first emission area EMA1 by an inkjet printing scheme, a slit coating scheme, or other various schemes.

The light emitting elements LD may include a first light emitting element LD1, a second light emitting element LD2, a third light emitting element LD3, and a fourth light emitting element LD4.

The first light emitting element LD1 may be aligned between a left upper end area of the first alignment electrode ALE1 and the second alignment electrode ALE2 and electrically connected to the first electrode ELT1 and the second electrode ELT2. The first light emitting element LD1 may include a first end EP1 disposed adjacent to the first alignment electrode ALE1, and a second end EP2 disposed adjacent to the second alignment electrode ALE2. The first end EP1 of the first light emitting element LD1 may be electrically connected to the first electrode ELT1. The second end EP2 of the first light emitting element LD1 may be electrically connected to the second electrode ELT2.

The second light emitting element LD2 may be aligned between a left lower end area of the first alignment electrode ALE1 and the second alignment electrode ALE2 and electrically connected to the second electrode ELT2 and the third electrode ELT3. The second light emitting element LD2 may include a first end EP1 disposed adjacent to the first alignment electrode ALE1, and a second end EP2 disposed adjacent to the second alignment electrode ALE2. The first end EP1 of the second light emitting element LD2 may be electrically connected to the second electrode ELT2. The second end EP2 of the second light emitting element LD2 may be electrically connected to the third electrode ELT3.

The third light emitting element LD3 may be aligned between a right lower end area of the first alignment electrode ALE1 and the second alignment electrode ALE2 and electrically connected to the third electrode ELT3 and the fourth electrode ELT4. The third light emitting element LD3 may include a first end EP1 disposed adjacent to the first alignment electrode ALE1, and a second end EP2 disposed adjacent to the second alignment electrode ALE2. The first end EP1 of the third light emitting element LD3 may be electrically connected to the third electrode ELT3. The second end EP2 of the third light emitting element LD3 may be electrically connected to the fourth electrode ELT4.

The fourth light emitting element LD4 may be aligned between a right upper end area of the first alignment electrode ALE1 and the second alignment electrode ALE2 and electrically connected to the fourth electrode ELT4 and the fifth electrode ELT5. The fourth light emitting element LD4 may include a first end EP1 disposed adjacent to the first alignment electrode ALE1, and a second end EP2 disposed adjacent to the second alignment electrode ALE2. The first end EP1 of the fourth light emitting element LD4 may be electrically connected to the fourth electrode ELT4. The second end EP2 of the fourth light emitting element LD4 may be electrically connected to the fifth electrode ELT5.

As described above, the first end EP1 of each of the first, second, third, and fourth light emitting elements LD1, LD2, LD3, and LD4 may be disposed adjacent to the corresponding first alignment electrode ALE1. The second end EP2 of each of the first, second, third, and fourth light emitting elements LD1, LD2, LD3, and LD4 may be disposed adjacent to the corresponding second alignment electrode ALE2.

Each of the first, second, third, and fourth light emitting elements LD1, LD2, LD3, and LD4 may be formed of a light emitting diode which is made of material having an inorganic crystal structure and has a subminiature size, e.g., ranging from the nano scale (or the nanometer scale) to the micro scale (or the micrometer scale).

The electrodes ELT may be provided at least in the first emission area EMA1, and each may be provided at a position corresponding to at least one alignment electrode ALE and the light emitting elements LD. For example, the electrodes ELT may be formed on the alignment electrodes ALE and/or the light emitting elements LD in such a way that each of the electrodes ELT overlaps the corresponding electrodes ALE and/or the corresponding light emitting elements LD, whereby the electrodes ELT may be electrically connected to the light emitting elements LD.

The first electrode ELT1 (or the first pixel electrode) may be disposed on a first area (e.g., the left upper end area) of the first alignment electrode ALE1 and the first ends EP1 of the first light emitting elements LD1, and thus electrically connected to the first ends EP1 of the first light emitting elements LD1. The first electrode ELT1 may be formed of the fifth conductive layer C5.

The second electrode ELT2 may be disposed both on a first area (e.g., an upper end area) of the second alignment electrode ALE2 that faces the first area of the first alignment electrode ALE1 and on the second ends EP2 of the first light emitting elements LD1, and thus electrically connected to the second ends EP2 of the first light emitting elements LD1. Furthermore, the second electrode ELT2 may be disposed on the second area (e.g., the left lower end area) of the first alignment electrode ALE1 and the first ends EP1 of the second light emitting elements LD2, and thus electrically connected to the first ends EP1 of the second light emitting elements LD2. For example, the second electrode ELT2 may be a first bridge electrode which electrically connects the second ends EP2 of the first light emitting elements LD1 and the first ends EP1 of the second light emitting elements LD2 to each other in the first emission area EMA1. To this end, the second electrode ELT2 may have a bent shape. For example, the second electrode ELT2 may have a bent or curved structure on a boundary between an area where at least one first light emitting element LD1 is disposed and an area where at least one second light emitting element LD2 is disposed. The second electrode ELT2 may be formed of the fifth conductive layer C5.

The third electrode ELT3 may be disposed on a second area (e.g., a lower end area) of the second alignment electrode ALE2 and the second ends EP2 of the second light emitting elements LD2, and thus electrically connected to the second ends EP2 of the second light emitting elements LD2. Furthermore, the third electrode ELT3 may be disposed on the third area (e.g., the right lower end area) of the first alignment electrode ALE1 and the first ends EP1 of the third light emitting elements LD3, and thus electrically connected to the first ends EP1 of the third light emitting elements LD3. For example, the third electrode ELT3 may be a second bridge electrode which electrically connects the second ends EP2 of the second light emitting elements LD2 and the first ends EP1 of the third light emitting elements LD3 to each other in the first emission area EMA1. To this end, the third electrode ELT3 may have a bent shape. For example, the third electrode ELT3 may have a bent or curved structure on a boundary between an area where at least one second light emitting element LD2 is disposed and an area where at least one third light emitting element LD3 is disposed. The third electrode ELT3 may be formed of the fifth conductive layer C5.

The fourth electrode ELT4 may be disposed both on the second area (e.g., the lower end area) of the second alignment electrode ALE2 that faces the third area of the first alignment electrode ALE1 and on the second ends EP2 of the third light emitting elements LD3, and thus electrically connected to the second ends EP2 of the third light emitting elements LD3. Furthermore, the fourth electrode ELT4 may be disposed on a fourth area (e.g., the right upper end area) of the first alignment electrode ALE1 and the first ends EP1 of the fourth light emitting elements LD4, and thus electrically connected to the first ends EP1 of the fourth light emitting elements LD4. For example, the fourth electrode ELT4 may be a third bridge electrode which electrically connects the second ends EP2 of the third light emitting elements LD3 and the first ends EP1 of the fourth light emitting elements LD4 to each other in the first emission area EMA1. To this end, the fourth electrode ELT4 may have a bent shape. For example, the fourth electrode ELT4 may have a bent or curved structure on a boundary between an area where at least one third light emitting element LD3 is disposed and an area where at least one fourth light emitting element LD4 is disposed. The fourth electrode ELT4 may be formed of the fifth conductive layer C5.

The fifth electrode ELT5 may be disposed on the first area (e.g., the upper end area) of the second alignment electrode ALE2 and the second ends EP2 of the fourth light emitting elements LD4, and thus electrically connected to the second ends EP2 of the fourth light emitting elements LD4. The fifth electrode ELT5 may be formed of the fifth conductive layer C5.

In this way, the light emitting elements LD aligned between the alignment electrodes ALE may be connected in a desired form by using the electrodes ELT. For example, the first light emitting elements LD1, the second light emitting elements LD2, the third light emitting elements LD3, and the fourth light emitting elements LD4 may be successively electrically connected in series by using the electrodes ELT.

The first electrode ELT1 of the first sub-pixel SPX1 may be electrically connected to the first contact electrode CNE1 through the first contactor CNT1. The first electrode ELT1 of the second sub-pixel SPX2 may be electrically connected to the second contact electrode CNE2 through the second contactor CNT2. The first electrode ELT1 of the third sub-pixel SPX3 may be electrically connected to the third contact electrode CNE3 through the third contactor CNT3. The electrodes ELT of each of the first, second, and third sub-pixels SPX1, SPX2, and SPX3 may be driving electrodes provided to drive the light emitting elements LD disposed in the emission area of the corresponding sub-pixel SPX.

The first emission component EMU1 may further include sub-electrodes SLT electrically connected to the electrodes ELT. The sub-electrodes SLT may include a first sub-electrode SLT1, a second sub-electrode SLT2, a third sub-electrode SLT3, and a fourth sub-electrode SLT4. The first sub-electrode SLT1 may be electrically connected to the second electrode ELT2. The second sub-electrode SLT2 may be electrically connected to the third electrode ELT3. The third sub-electrode SLT3 may be electrically connected to the fourth electrode ELT4. The fourth sub-electrode SLT4 may be electrically connected to the fifth electrode ELT5.

The first, second, third, and fourth sub-electrodes SLT1, SLT2, SLT3, and SLT4 may be formed of the fifth conductive layer C5. The first sub-electrode SLT1 may be integrally formed with the second electrode ELT2 and thus connected to the second electrode ELT2. The second sub-electrode SLT2 may be integrally formed with the third electrode ELT3 and thus connected to the third electrode ELT3. The third sub-electrode SLT3 may be integrally formed with the fourth electrode ELT4 and thus connected to the fourth electrode ELT4. The fourth sub-electrode SLT4 may be integrally formed with the fifth electrode ELT5 and thus connected to the fifth electrode ELT5. However, the present disclosure is not limited to the aforementioned examples.

In the case in which there are provided the sub-electrodes SLT electrically connected to the electrodes ELT, a dark spot defect of the first sub-pixel SPX1 (or the pixel PXL) may be mitigated. The sub-electrodes SLT may be disposed over the bank BNK, and may overlap the bank BNK. For example, each of the first, second, third, and fourth sub-electrodes SLT1, STL2, STL3, and SLT4 may be disposed over the bank BNK, and may overlap the bank BNK in a plan view.

At least one of the sub-electrodes SLT of the first sub-pixel SPX1 may be electrically connected to at least one of the sub-electrodes SLT of an adjacent sub-pixel SPX. For example, the fourth sub-electrode SLT4 of the first sub-pixel SPX1 may be electrically connected to the fourth sub-electrode SLT4 of the second sub-pixel SPX2.

At least one of the sub-electrodes SLT of the sub-pixel SPX may be electrically connected to at least one of the sub-electrodes SLT of an adjacent sub-pixel SPX by an intermediate electrode IE. For example, the fourth sub-electrode SLT4 of the first sub-pixel SPX1 may be electrically connected to the fourth sub-electrode SLT4 of the second sub-pixel SPX2 by an intermediate electrode IE.

The intermediate electrode IE may be disposed on a boundary between adjacent sub-pixels SPX or in space therebetween, e.g., in the non-emission area NEA, and may be connected to at least one of the sub-electrodes SLT of each of the adjacent sub-pixels SPX. The intermediate electrode IE may be integrally provided with at least one of the sub-electrodes SLT of the sub-pixels SPX and disposed in the same layer as the at least one, but the present disclosure is not limited thereto. The intermediate electrode IE may be formed of the fifth conductive layer C5.

The fourth sub-electrode SLT4 of the first sub-pixel SPX1 may be spaced apart from the fourth sub-electrode SLT4 of the second sub-pixel SPX2. The fourth sub-electrode SLT4 of the first sub-pixel SPX1 and the fourth sub-electrode SLT4 of the second sub-pixel SPX2 may be electrically connected to each other by the intermediate electrode IE. The intermediate electrode IE may be integrally provided with the fourth sub-electrode SLT4 of the first sub-pixel SPX1 and/or the fourth sub-electrode SLT4 of the second sub-pixel SPX2 and disposed on a layer identical thereto, but the present disclosure is not limited thereto.

Although there is illustrated the case where the sub-electrodes SLT of the third sub-pixel SPX3 are separated from the sub-electrodes SLT of the first sub-pixel SPX1 and/or the sub-electrodes SLT of the second sub-pixel SPX2, the present disclosure is not limited thereto. In an embodiment, at least one of the sub-electrodes SLT of the third sub-pixel SPX3 may be electrically connected to at least one of the sub-electrodes SLT of the first sub-pixel SPX1 and/or the sub-electrodes SLT of the second sub-pixel SPX2.

A bridge line BRL may be disposed between adjacent sub-pixels SPX (or the pixels PXL) provided on different pixel rows. The bridge line BRL may extend in the first direction DR1, and may be electrically connected to at least one of the electrodes ELT of each of the first, second, and third sub-pixels SPX1, SPX2, and SPX3. The bridge line BRL may be formed of the fifth conductive layer C5. The bridge line BRL may be electrically connected to the second power line PL2 of the pixel circuit layer PCL, and may be supplied with the voltage of the second driving power supply VSS.

In an embodiment, the fifth electrode ELT5 of each of the first, second, and third sub-pixels SPX1, SPX2, and SPX3 may be electrically connected to the bridge line BRL. The fifth electrode ELT5 of each of the first, second, and third sub-pixels SPX1, SPX2, and SPX3 may be integrally formed with the bridge line BRL, and may diverge from the bridge line BRL and extend in the second direction DR2. The bridge line BRL and the respective fifth electrodes ELT5 of the first, second, and third sub-pixels SPX1, SPX2, and SPX3 may form a mesh structure. Because the bridge line BRL and the fifth electrode ELT5 of each of the first, second, and third sub-pixels SPX1, SPX2, and SPX3 are electrically connected to each other, the fifth electrode ELT5 of the first sub-pixel SPX1, the fifth electrode ELT5 of the second sub-pixel SPX2, and the fifth electrode ELT5 of the third sub-pixel SPX3 may be electrically connected to each other.

As described above, in the case in which the fifth electrodes ELT5 that are cathodes are connected to each other and connected to the bridge line BRL to form a mesh structure among the electrodes ELT of adjacent sub-pixels SPX, the number of contacts on the bridge line BRL may be reduced so that design space can be secured in the display device having a high resolution, a contact resistance can be reduced, and electrostatic discharge can be improved.

Hereinafter, a stack structure (or a cross-sectional structure) of the first sub-pixel SPX1 will be described in detail with reference to FIG. 12.

The first sub-pixel SPX1 may include a display component LEL that includes the substrate SUB, the pixel circuit layer PCL, and the display element layer DPL.

The pixel circuit layer PCL and the display element layer DPL may be disposed on one surface of the substrate SUB and overlap each other.

The pixel circuit layer PCL may include a first insulating layer INS1, a second insulating layer INS2, a third insulating layer INS3, a fourth insulating layer IN4S, and a fifth insulating layer INS5 which are successively stacked on the substrate SUB.

The display element layer DPL may include bank patterns BNP, first and second alignment electrodes ALE1 and ALE2, light emitting elements LD, electrodes ELT, a sixth insulating layer INS6, a seventh insulating layer INS7 and/or sub-electrodes SLT.

The bank patterns BNP may be disposed on the fifth insulating layer INS5 of the pixel circuit layer PCL and may have reflectivity. For example, the bank patterns BNP along with the first alignment electrode ALE1 and the second alignment electrode ALE2 disposed thereover may be used as reflectors which guide light emitted from the light emitting element LD in a desired direction so that the light output efficiency of each of the first, second, and third sub-pixels SPX1, SPX2, and SPX3 can be enhanced.

The first alignment electrode ALE1 and the second alignment electrode ALE2 may be disposed on the bank patterns BNP.

The first alignment electrode ALE1 and the second alignment electrode ALE2 may be disposed on the same plane, and have the same thickness in the third direction DR3. The first alignment electrode ALE1 and the second alignment electrode ALE2 may be simultaneously formed through the same process.

The sixth insulating layer INS6 may be disposed on the first and second alignment electrodes ALE1 and ALE2.

The sixth insulating layer INS6 may be provided and/or formed on overall surfaces of the first and second alignment electrodes ALE1 and ALE2.

The bank BNK may be disposed on the sixth insulating layer INS6.

The bank BNK may be disposed on the sixth insulating layer INS6 in the non-emission area NEA. The bank BNK may surround the first emission area EMA1 of the first sub-pixel SPX1.

The light emitting elements LD may be disposed on the sixth insulating layer INS6. The light emitting elements LD may be disposed on the sixth insulating layer INS6 between adjacent alignment electrodes ALE.

The light emitting elements LD may include a first light emitting element LD1, a second light emitting element LD2, a third light emitting element LD3, and a fourth light emitting element LD4.

The seventh insulating layer INS7 (or an insulating pattern) may be disposed on each of the first, second, third, and fourth light emitting elements LD1, LD2, LD3, and LD4. The seventh insulating layer INS7 may be disposed on each of the first, second, third, and fourth light emitting elements LD1, LD2, LD3, and LD4, and partially cover an outer circumferential surface (or a surface) of each of the first, second, third, and fourth light emitting elements LD1, LD2, LD3, and LD4 such that the first end EP1 and the second end EP2 of each of the first, second, third, and fourth light emitting elements LD1, LD2, LD3, and LD4 are exposed to the outside.

The seventh insulating layer INS7 may be provided and/or formed on the sixth insulating layer INS6 in the emission area EMA.

The seventh insulating layer INS7 may include an inorganic layer including inorganic material, or an organic layer including organic material. For example, the seventh insulating layer INS7 may include an inorganic layer suitable for protecting the active layer (reference numeral 12 of FIG. 1) of each of the first, second, third, and fourth light emitting elements LD1, LD2, LD3, and LD4 from external oxygen, water, or the like. However, the present disclosure is not limited thereto. The seventh insulating layer INS7 may be formed of an organic layer, depending on design conditions and the like of the display device DD (or the display panel DP) to which the first, second, third, and fourth light emitting elements LD1, LD2, LD3, and LD4 are applied. The seventh insulating layer INS7 may have a single-layer or multilayer structure.

In case that a gap (or space) is present between the sixth insulating layer INS6 and the light emitting elements LD before the formation of the seventh insulating layer INS7, the gap may be filled with the seventh insulating layer INS7 during a process of forming the seventh insulating layer INS7.

Because the seventh insulating layer INS7 is formed on the first, second, third, and fourth light emitting elements LD1, LD2, LD3, and LD4 that have been completely aligned in the first emission area EMA1, the first, second, third, and fourth light emitting elements LD1, LD2, LD3, and LD4 may be prevented from being removed from the aligned positions thereof.

The electrodes ELT may be formed on the opposite ends of the light emitting elements LD, i.e., the first and second ends EP1 and EP2, which are not covered with the seventh insulating layer INS7.

The first electrode ELT1, the second electrode ELT2, the third electrode ELT3, the fourth electrode ELT4, and/or the fifth electrode ELT5 may be formed of the fifth conductive layer C5 disposed on the seventh insulating layer INS7. The first electrode ELT1, the second electrode ELT2, the third electrode ELT3, the fourth electrode ELT4, and/or the fifth electrode ELT5 may be simultaneously formed through the same process.

Each of the electrodes ELT may be formed of various transparent conductive materials. For example, each of the electrodes ELT may include at least one of various transparent conductive materials including indium tin oxide, indium zinc oxide, indium tin zinc oxide, aluminum zinc oxide, gallium zinc oxide, zinc tin oxide, or gallium tin oxide, and may be substantially transparent or translucent to provide satisfactory transmittance. Hence, light emitted from the light emitting elements LD in the active layer 12 (see FIG. 1) may be emitted out of the display panel DP.

The sub-electrodes SLT may be disposed in the same layer as the respective electrodes ELT, and may have the same material as the electrodes ELT. The sub-electrodes SLT and the electrodes ELT that are electrically connected to each other may be integrally formed through the same process.

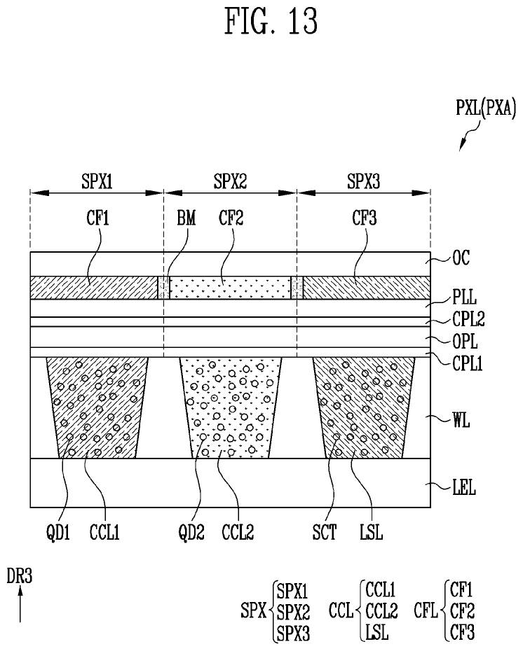

FIG. 13 is a schematic cross-sectional view illustrating the first to third sub-pixels SPX1, SPX2, and SPX3 in accordance with an embodiment.

For example, FIG. 13 illustrates an optical layer which includes a partition wall WL, a color conversion layer CCL, a color filter layer CFL, and/or an overcoat layer OC which are provided on the display component LEL of each sub-pixel SPX described with reference to FIGS. 10 to 12. The optical layer may correspond to the optical layer LCL of FIG. 4.

Referring to FIGS. 1 to 13, the partition wall WL (e.g., “dam structure” or “wall structure”) may be disposed on the display component LEL for the first to third sub-pixels SPX1, SPX2, and SPX3. For example, the partition wall WL may be disposed between the first to third sub-pixels SPX1, SPX2, and SPX3 or on boundaries therebetween, and include openings which respectively are disposed in areas corresponding to the first to third sub-pixels SPX1, SPX2, and SPX3. Each of the openings of the partition wall WL may provide space in which the color conversion layer CCL can be provided.

The partition wall WL may include organic material (or substance) such as acrylic resin, epoxy resin, phenolic resin, polyamide resin, polyimide resin, polyester resin, polyphenylene sulfide resin, or benzocyclobutene (BCB). However, the present disclosure is not limited thereto. The partition wall WL may include various inorganic materials (or substances) including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In an embodiment, the partition wall WL may include at least one light blocking material and/or reflective material. Therefore, a light leakage between adjacent sub-pixels SPX may be prevented from being caused. For example, the partition wall WL may include at least one black matrix material and/or color filter material. For instance, the partition wall WL may be formed of a black opaque pattern which can block transmission of light. In an embodiment, a reflective layer (not illustrated) or the like may be formed on a surface (e.g., a sidewall) of the partition wall WL to increase the light efficiency of each sub-pixel SPX.

The color conversion layer CCL may be disposed on the display component LEL including the light emitting elements LD in the openings of the partition wall WL. The color conversion layer CCL may include a first color conversion layer CCL1 disposed in the first sub-pixel SPX1, a second color conversion layer CCL2 disposed in the second sub-pixel SPX2, and a light scattering layer LSL disposed in the third sub-pixel SPX3.

In an embodiment, the first to third sub-pixels SPX1, SPX2, and SPX3 may include light emitting elements LD configured to emit the same color of light. For example, the first to third sub-pixels SPX1, SPX2, and SPX3 may include light emitting elements LD configured to emit a third color of light (or blue light). Because the color conversion layer CCL including color conversion particles is disposed in each of the first to third sub-pixels SPX1, SPX2, and SPX3, a full-color image may be displayed.

The first color conversion layer CCL1 may include first color conversion particles for converting the third color of light emitted from the light emitting element LD to the first color of light. For example, the first color conversion layer CCL1 may include a plurality of first quantum dots QD1 which are dispersed in a matrix material such as base resin.

In the case in which the light emitting element LD is a blue light emitting element configured to emit blue light and the first sub-pixel SPX1 is a red pixel, the first color conversion layer CCL1 may include the first quantum dots QD1 which may convert blue light emitted from the blue light emitting element to red light. The first quantum dots QD1 may absorb blue light, shift the wavelength thereof according to an energy transition, and thus emit red light. In an embodiment, in the case in which the first sub-pixel SPX1 is one of pixels of other colors, the first color conversion layer CCL1 may include the first quantum dots QD1 corresponding to the color of the first sub-pixel SPX1.

The second color conversion layer CCL2 may include second color conversion particles for converting the third color of light emitted from the light emitting element LD to the second color of light. For example, the second color conversion layer CCL2 may include a plurality of second quantum dots QD2 which are dispersed in a matrix material such as base resin.

In an embodiment, in the case where the light emitting element LD is a blue light emitting element configured to emit blue light and the second sub-pixel SPX2 is a green pixel, the second color conversion layer CCL2 may include the second quantum dots QD2 which may convert blue light emitted from the blue light emitting element to green light. The second quantum dots QD2 may absorb blue light, shift the wavelength thereof according to an energy transition, and thus emit green light. In an embodiment, in the case in which the second sub-pixel SPX2 is one of pixels of other colors, the second color conversion layer CCL2 may include the second quantum dots QD2 corresponding to the color of the second sub-pixel SPX2.

In an embodiment, as blue light having a relatively short wavelength in a visible ray area is incident on each of the first quantum dots QD1 and the second quantum dots QD2, absorption coefficients of the first quantum dot QD1 and the second quantum dot QD2 may be increased. Therefore, eventually, the efficiency of light emitted from the first sub-pixel SPX1 and the second sub-pixel SPX2 may be enhanced, and satisfactory color reproducibility may be secured. Furthermore, since the emission component for the first to third sub-pixels SPX1, SPX2, and SPX3 is formed of light emitting elements LD (e.g., blue light emitting elements) configured to emit the same color of light, the efficiency of fabricating the display device DD may be enhanced.

The light scattering layer LSL may be provided to efficiently use the third color of light (or blue light) emitted from the light emitting element LD. For example, in the case where the light emitting element LD is a blue light emitting element configured to emit blue light and the third sub-pixel SPX3 is a blue pixel, the light scattering layer LSL may include at least one type of light scatterer SCT to efficiently use light emitted from the light emitting element LD.

For example, the light scattering layer LSL may include a plurality of light scatterers SCT which are dispersed in a matrix material such as base resin. For instance, the light scattering layer LSL may include light scatterers SCT formed of material such as silica, but the constituent material of the light scatterers SCT is not limited thereto. The light scatterers SCT may not only be provided in the third sub-pixel SPX3, but may also be selectively included in the first conversion layer CCL1 or the second color conversion layer CCL2. In an embodiment, the light scatterers SCT may be omitted, and the light scattering layer LSL may be formed of transparent polymer.

A first capping layer CPL1 may be disposed on the color conversion layer CCL. The first capping layer CPL1 may be provided over the first to third sub-pixels SPX1, SPX2, and SPX3. The first capping layer CPL1 may cover the color conversion layer CCL. The first capping layer CPL1 may prevent the color conversion layer CCL from being damaged or contaminated by permeation of external impurities such as water or air.

The first capping layer CPL1 may be an inorganic layer including inorganic material, and be formed of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), or silicon oxynitride (SiOₓN_{y}).

A refractive index conversion layer OPL may be disposed on the first capping layer CPL1. The refractive index conversion layer OPL may function to recycle light provided from the color conversion layer CCL by total reflection and thus enhance light extraction efficiency. Hence, the refractive index conversion layer OPL may have a relatively low refractive index compared to that of the color conversion layer CCL. For example, the refractive index of the color conversion layer CCL may approximately range from 1.6 to 2.0, and the refractive index of the refractive index conversion layer OPL may approximately range from 1.1 to 1.3.

A second capping layer CPL2 may be disposed on the refractive index conversion layer OPL. The second capping layer CPL2 may be provided over the first to third sub-pixels SPX1, SPX2, and SPX3. The second capping layer CPL2 may cover the refractive index conversion layer OPL. The second capping layer CPL2 may prevent the optical layer OPL from being damaged or contaminated by permeation of external impurities such as water or air.

The second capping layer CPL2 may be an inorganic layer including inorganic material, and be formed of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), or silicon oxynitride (SiOₓN_{y}).

A planarization layer PLL may be disposed on the second capping layer CPL2. The planarization layer PLL may be provided over the first to third sub-pixels SPX1, SPX2, and SPX3.

The planarization layer PLL may include organic material (or substance) such as acrylic resin, epoxy resin, phenolic resin, polyamide resin, polyimide resin, polyester resin, polyphenylene sulfide resin, or benzocyclobutene (BCB). However, the present disclosure is not limited thereto. The planarization layer PLL may include various inorganic materials (or substances) including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The color filter layer CFL may be disposed on the planarization layer PLL. The color filter layer CFL may include color filters CF1, CF2, and CF3 corresponding to the colors of the respective sub-pixels SPX. Because the color filters CF1, CF2, and CF3 corresponding to the respective colors of the first to third sub-pixels SPX1, SPX2, and SPX3 are disposed, a full-color image may be displayed.

The color filter layer CFL may include a first color filter CF1 disposed in the first sub-pixel SPX1 and configured to allow light emitted from the first color conversion layer CCL1 to selectively pass therethrough, a second color filter CF2 disposed in the second sub-pixel SPX2 and configured to allow light emitted from the second color conversion layer CCL2 to selectively pass therethrough, and a third color filter CF3 disposed in the third sub-pixel SPX3 and configured to allow light emitted from the light scattering layer to selectively pass therethrough.

The first color filter CF1, the second color filter CF2, and the third color filter CF3 may be respectively a red color filter, a green color filter, and a blue color filter, but the present disclosure is not limited thereto.

The first color filter CF1 may overlap the display component LEL (or the light emitting elements LD) of the first sub-pixel SPX1 and the first color conversion layer CCL1 in the third direction DR3. The first color filter CF1 may include color filter material for allowing the first color of light (or red light) to selectively pass therethrough. For example, in the case in which the first sub-pixel SPX1 is a red pixel, the first color filter CF1 may include red color filter material.

The second color filter CF2 may overlap the display component LEL (or the light emitting elements LD) of the second sub-pixel SPX2 and the second color conversion layer CCL2 in the third direction DR3. The second color filter CF2 may include color filter material for allowing the second color of light (or green light) to selectively pass therethrough. For example, in the case in which the second sub-pixel SPX2 is a green pixel, the second color filter CF2 may include green color filter material.

The third color filter CF3 may overlap the display layer LEL (or the light emitting elements LD) of the third sub-pixel SPX3 and the light scattering layer LSL in the third direction DR3. The third color filter CF3 may include color filter material for allowing the third color of light (or blue light) to selectively pass therethrough. For example, in the case in which the third sub-pixel SPX3 is a blue pixel, the third color filter CF3 may include blue color filter material.

A light blocking layer BM may be disposed between the first to third color filters CF1, CF2, and CF3. The light blocking layer BM may be disposed between the first to third sub-pixels SPX1, SPX2, and SPX3 or on boundaries therebetween. The material of the light blocking layer BM is not particularly limited. Various light blocking materials including black matrix material may be used to form the light blocking layer BM. In the case in which the light blocking layer BM is formed between the first to third color filters CF1, CF2, and CF3, a color mixing defect which is visible from a front surface or side surface of the display device DD may be prevented from occurring. In an embodiment, the light blocking layer BM may be omitted, and the first, second, and third color filters CF1, CF2, and CF3 may be disposed to overlap each other between adjacent sub-pixels SPX and thus used as a light blocking component for blocking light interference between the adjacent sub-pixels SPX.

An overcoat layer OC may be disposed on the color filter layer CFL. The overcoat layer OC may be provided over the first to third sub-pixels SPX1, SPX2, and SPX3. The overcoat layer OC may cover a lower component including the color filter layer CFL. The overcoat layer OC may prevent water or air from permeating the underlying component. Furthermore, the overcoat layer OC may protect the underlying component from foreign material such as dust.

The overcoat layer OC may include organic material (or substance) such as acrylic resin, epoxy resin, phenolic resin, polyamide resin, polyimide resin, polyester resin, polyphenylene sulfide resin, or benzocyclobutene (BCB). However, the present disclosure is not limited thereto. The overcoat layer OC may include various inorganic materials (or substances) including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

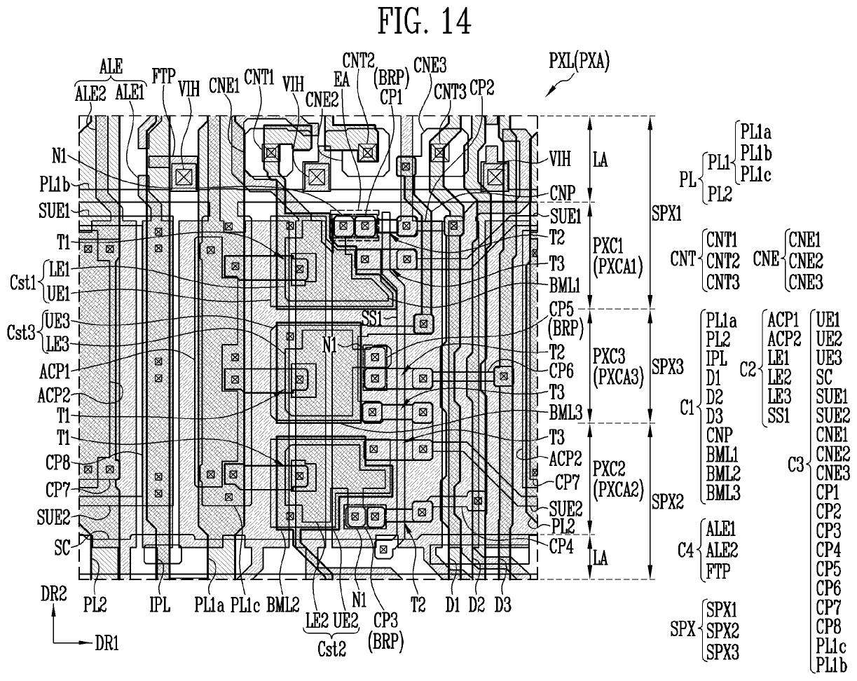

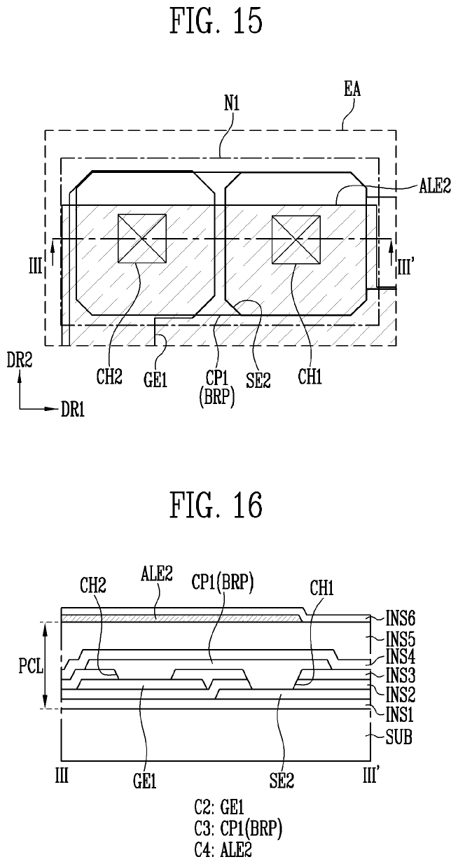

FIG. 14 is a schematic plan view illustrating a pixel PXL including an alignment electrode ALE based on the pixel of FIG. 6. FIG. 15 is a schematic enlarged view of portion EA of FIG. 14. FIG. 16 is a schematic cross-sectional view taken along line III-III′ of FIG. 15.

The description with reference to FIGS. 14 to 16 will be focused on differences from the above-mentioned embodiments so as to avoid redundant description.

Referring to FIGS. 1 to 16, the pixel PXL may include a first conductive layer C1, a second conductive layer C2, a third conductive layer C3, and a fourth conductive layer C4, which are successively formed on a certain surface of the substrate SUB.

The first conductive layer C1 may include the first vertical power line PL1a, the second power line PL2, the initialization power line IPL, the first data line D1, the second data line D2, the third data line D3, the first bottom metal pattern BML1, the second bottom metal pattern BML2, the third bottom metal pattern BML3, and the connection pattern CNP which are disposed on the substrate SUB at positions spaced apart from each other.

The second conductive layer C2 may include the first additional conductive pattern ACP1, the second additional conductive pattern ACP2, the first lower electrode LE1, the second lower electrode LE2, the third lower electrode LE3, and the sub-scan line SS1 which are disposed on the second insulating layer INS2 at positions spaced apart from each other.

The third conductive layer C3 may include the first to eighth conductive patterns CP1 to CP8, the first and second sub-electrodes SUE1 and SUE2, the first upper electrode UE1, the second upper electrode UE2, the third upper electrode UE3, the scan line SC, the first contact electrode CNE1, the second contact electrode CNE2, and the third contact electrode CNE3 which are disposed on the third insulating layer INS3 at positions spaced apart from each other.

The fourth conductive layer C4 may include the first alignment electrode ALE1, the second alignment electrode ALE2, and the floating pattern FTP, which are disposed on the fifth insulating layer INS5 at positions spaced apart from each other.

A conductive pattern corresponding to a bridge pattern may be disposed in an area corresponding to the first node N1 (e.g., a connection point between the first gate electrode G1 of the first transistor T1 and the second source electrode SE2 of the second transistor T2) of each sub-pixel SPX (or each pixel circuit). For example, the first conductive pattern CP1 may be positioned on the first node N1 of the first sub-pixel SPX1 (or the first pixel circuit PXC1). The third conductive pattern CP3 may be positioned on the first node N1 of the second sub-pixel SPX2 (or the second pixel circuit PXC2). The fifth conductive pattern CP5 may be positioned on the first node N1 of the third sub-pixel SPX3 (or the third pixel circuit PXC3).

In the first sub-pixel SPX1, the first conductive pattern CP1 may overlap the first gate electrode GE1 of the first transistor T1 and the second source electrode SE2 of the second transistor. A first end of the first conductive pattern CP1 may be electrically connected to the second source electrode SE2 of the second transistor T2 through a first contact hole CH1 formed through the second and third insulating layers INS2 and INS3. A second end of the first conductive pattern CP1 may be electrically connected to the first gate electrode GE1 of the first transistor T1 through a second contact hole CH2 that is formed through the third insulating layer INS3. The first node N1 may correspond to an area where the first contact hole CH1 and the second contact hole CH2 are positioned and may be a connection point between the first gate electrode GE1 of the first transistor T1 and the second source electrode SE2 of the second transistor T2.

The second alignment electrode ALE2 may be disposed on the first node N1 of the first sub-pixel SPX1. For example, the second alignment electrode ALE2 may be disposed on the first conductive pattern CP1 (or the bridge pattern BRP) which connects the first gate electrode GE1 of the first transistor T1 and the second source electrode SE2 of the second transistor T2 which constitutes the first node N1. The second alignment electrode ALE2 may be disposed on the first conductive pattern CP1 with the fourth and fifth insulating layers INS4 and INS5 interposed therebetween. The second alignment electrode ALE2 may overlap the first conductive pattern CP1, and the first and second contact holes CH1 and CH2 on the first node N1 in a plan view. The second alignment electrode ALE2 may partially overlap the first conductive pattern CP1 and may completely overlap the first and second contact holes CH1 and CH2 on the first node N1 in a plan view. For example, the second alignment electrode ALE2 may overlap a first edge of the first conductive pattern CP1 and may not overlap a second edge opposing the first edge along the second direction D2 in a plan view.

In the second sub-pixel SPX2, the third conductive pattern CP3 may overlap the first gate electrode GE1 of the first transistor T1 and the second source electrode SE2 of the second transistor T2. A first end of the third conductive pattern CP3 may be electrically connected to the second source electrode SE2 of the second transistor T2 through a contact hole that is formed through the second and third insulating layers INS2 and INS3. A second end of the third conductive pattern CP3 may be electrically connected to the first gate electrode GE1 of the first transistor T1 through a contact hole that is formed through the third insulating layer INS3. The first node N1 may correspond to an area where the aforementioned contact holes are positioned and may be a connection point between the first gate electrode GE1 of the first transistor T1 and the second source electrode SE2 of the second transistor T2.

The second alignment electrode ALE2 may be disposed on the first node N1 of the second sub-pixel SPX2. For example, the second alignment electrode ALE2 may be disposed on the third conductive pattern CP3 (or the bridge pattern BRP) which connects the first gate electrode GE1 of the first transistor T1 and the second source electrode SE2 of the second transistor T2 which constitutes the first node N1. The second alignment electrode ALE2 may be disposed on the fifth insulating layer INS5. The second alignment electrode ALE2 may overlap the third conductive pattern CP3 and the aforementioned contact holes on the first node N1 in a plan view.

In the third sub-pixel SPX3, the fifth conductive pattern CP5 may overlap the first gate electrode GE1 of the first transistor T1 and the second source electrode SE2 of the second transistor T2. A first end of the fifth conductive pattern CP5 may be electrically connected to the second source electrode SE2 of the second transistor T2 through a contact hole that is formed through the second and third insulating layers INS2 and INS3. A second end of the fifth conductive pattern CP5 may be electrically connected to the first gate electrode GE1 of the first transistor T1 through a contact hole that is formed through the third insulating layer INS3. The first node N1 may correspond to an area where the aforementioned contact holes are positioned and may be a connection point between the first gate electrode GE1 of the first transistor T1 and the second source electrode SE2 of the second transistor T2.

The second alignment electrode ALE2 may be disposed on the first node N1 of the third sub-pixel SPX3. For example, the second alignment electrode ALE2 may be disposed on the fifth conductive pattern CP5 positioned on the first node N1. The second alignment electrode ALE2 may be disposed on the fifth insulating layer INS5. The second alignment electrode ALE2 may overlap the fifth conductive pattern CP5 (or the bridge pattern BRP) which connects the first gate electrode GE1 of the first transistor T1 and the second source electrode SE2 of the second transistor T2 which constitutes the first node N1.

The second alignment electrode ALE2 may be electrically connected to the second power line PL2. A voltage of the second driving power supply VSS may be applied from the second power line PL2 to the second alignment electrode ALE2. The second alignment electrode ALE2 may extend in the second direction DR2 and may have a plate shape which overlaps the first conductive pattern CP1, the fifth conductive pattern CP5, and the third conductive pattern CP3 which are arranged in the second direction DR2 to cover all of the first conductive pattern CP1, the fifth conductive pattern CP5, and the third conductive pattern CP3.

In an embodiment, the second alignment electrode ALE2 may be used as a shielding component to reduce or minimize coupling capacitance (e.g., parasitic capacitance) occurring between the first node N1 of the first sub-pixel SPX1 and the first node N1 of the third sub-pixel SPX3. Furthermore, the second alignment electrode ALE2 may be used as a shielding component to reduce or minimize coupling capacitance occurring between the first node N1 of the third sub-pixel SPX3 and the first node N1 of the second sub-pixel SPX2.

In detail, as the second alignment electrode ALE2 configured to receive the voltage of the second driving power supply VSS is disposed on the first node N1 of each of the first, second, and third sub-pixels SPX1, SPX2, and SPX3, a phenomenon in which a change in voltage (or signal) applied to the first node N1 of the first sub-pixel SPX1 causes a change in voltage (or signal) applied to the first node N1 of the third sub-pixel SPX3 which is an adjacent sub-pixel SPX can be reduced or prevented. Furthermore, as the second alignment electrode ALE2 configured to receive the voltage of the second driving power supply VSS is disposed on the first node N1 of each of the first, second, and third sub-pixels SPX1, SPX2, and SPX3, a phenomenon in which a change in voltage (or signal) applied to the first node N1 of the third sub-pixel SPX3 causes a change in voltage (or signal) applied to the first node N1 of the second sub-pixel SPX2 which is an adjacent sub-pixel SPX can be reduced or prevented.

Accordingly, the second alignment electrode ALE2 may be used as a shielding component to reduce or minimize the coupling capacitance (e.g., parasitic capacitance) occurring between the first node N1 of the first sub-pixel SPX1 and the first node N1 of the third sub-pixel SPX3 and the coupling capacitance (e.g., parasitic capacitance) occurring between the first node N1 of the third sub-pixel SPX3 and the first node N1 of the second sub-pixel SPX2.

Furthermore, the second alignment electrode ALE2 may be positioned on the first node N1 of the first sub-pixel SPX1 to overlap the first node N1 in a plan view, thus reducing or minimizing coupling capacitance occurring between the first node N1 and the contactor CNT of an adjacent sub-pixel SPX.

According to the aforementioned embodiment, the parasitic capacitance of each sub-pixel SPX may be reduced, whereby the reliability of the display device (refer to DD of FIG. 3) can be enhanced.

According to the aforementioned embodiment, the line width of each of the first data line D1 electrically connected to the first sub-pixel SPX1, the second data line D2 electrically connected to the second sub-pixel SPX2, and the third data line D3 electrically connected to the third sub-pixel SPX3 may be reduced, for example, reduced from approximately 10.5 μm in a conventional art to approximately 7 μm in the embodiment, thus decreasing the surface area occupied by the first, second, and third data lines D1, D2, and D3 in each pixel PXL. In this case, the reduced surface area (or size) of the first, second, and third data lines D1, D2, and D3 in each pixel PXL can be used to secure the surface area of the storage capacitor of the corresponding pixel PXL.

Specifically, in the first sub-pixel SPX1, the reduced surface area of the first, second, and third data lines D1, D2, and D3 may be used to increase the surface area of the first bottom metal pattern BML1 and the respective surface areas of the first lower electrode LE1 that overlaps the first bottom metal pattern BML1 and the first upper electrode UE1 that overlaps the first lower electrode LE1. Accordingly, the overlapping surface area of the first bottom metal pattern BML1, the first lower electrode LE1, and the first upper electrode UE1 that overlap each other with the insulating layers interposed therebetween is further increased, thus leading to improvement in the capacitance of the first storage capacitor Cst1.

In the second sub-pixel SPX2, the reduced surface area of the first, second, and third data lines D1, D2, and D3 may be used to increase the surface area of the second bottom metal pattern BML2 and the respective surface areas of the second lower electrode LE2 that overlaps the second bottom metal pattern BML2 and the second upper electrode UE2 that overlaps the second lower electrode LE2. Accordingly, the overlapping surface area of the second bottom metal pattern BML2, the second lower electrode LE2, and the second upper electrode UE2 that overlap each other with the insulating layers interposed therebetween is further increased, thus leading to improvement in the capacitance of the second storage capacitor Cst2.

In the third sub-pixel SPX3, the reduced surface area of the first, second, and third data lines D1, D2, and D3 may be used to increase the surface area of the third bottom metal pattern BML3 and the respective surface areas of the third lower electrode LE3 that overlaps the third bottom metal pattern BML3 and the third upper electrode UE3 that overlaps the third lower electrode LE3. Accordingly, the overlapping surface area of the third bottom metal pattern BML3, the third lower electrode LE3, and the third upper electrode UE3 that overlap each other with the insulating layers interposed therebetween is further increased, thus leading to improvement in the capacitance of the third storage capacitor Cst3.

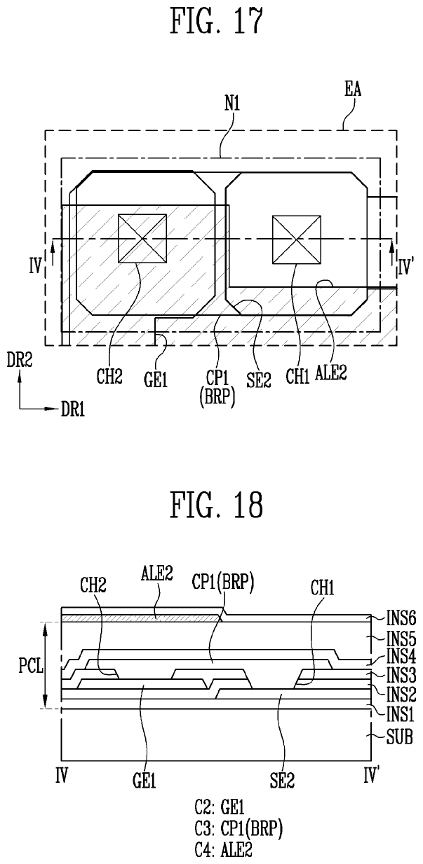

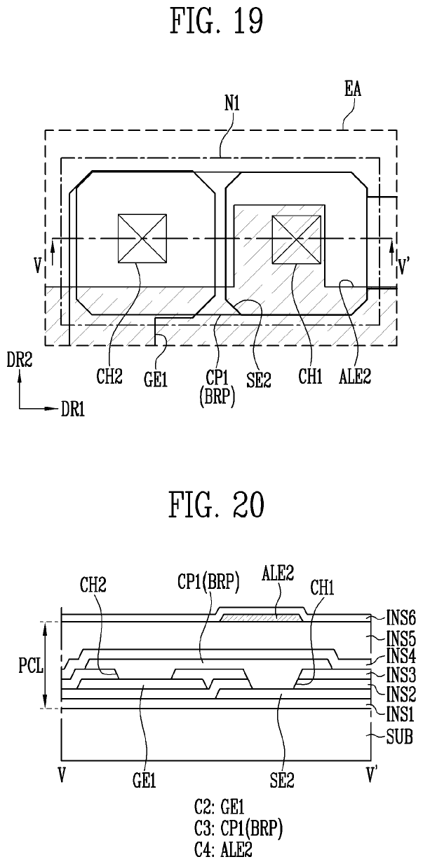

FIG. 17 is a schematic enlarged view of portion EA of FIG. 14 in accordance with another embodiment. FIG. 18 is a schematic cross-sectional view taken along line IV-IV′ of FIG. 17. FIG. 19 is a schematic enlarged view of portion EA of FIG. 14 in accordance with another embodiment. FIG. 20 is a schematic cross-sectional view taken along line V-V′ of FIG. 19.

An embodiment of FIGS. 17 to 20 illustrates a modification of the embodiment shown in FIGS. 15 and 16 with regard to the overlapping area of the second alignment electrode ALE2 and the first conductive pattern CP1.

The description of the embodiment of FIGS. 17 to 20 will be focused on differences from the above-mentioned embodiments so as to avoid redundant description.

Referring to FIGS. 14, and 17 to 20, the second alignment electrode ALE2 may be disposed on the first node N1 in the first sub-pixel SPX1. For example, the second alignment electrode ALE2 may be disposed on the first conductive pattern CP1 disposed in an area corresponding to the first node N1. The second alignment electrode ALE2 may be disposed on the first conductive pattern CP1 with the fourth and fifth insulating layers INS4 and INS5 interposed therebetween.

The second alignment electrode ALE2 may partially overlap the first conductive pattern CP1 on the first node N1.

For example, as illustrated in FIGS. 17 and 18, the second alignment electrode ALE2 may overlap the second contact hole CH2 and may not overlap the first contact hole CH1 in a plan view. The second alignment electrode ALE2 may completely overlap the second contact hole CH2 and may not overlap the first contact hole CH1 in a plan view. The second alignment electrode ALE2 may overlap the first edge of the first conductive pattern CP1 and the second contact hole CH2 on the first node N1 in a plan view. For example, the width of the second alignment electrode ALE2 along the second direction in an area overlapping the first gate electrode GE1 may be greater than the width of the second alignment electrode ALE2 along the second direction in an area overlapping the second source area SE2.

In an embodiment, as illustrated in FIGS. 19 and 20, the second alignment electrode ALE2 may overlap the first contact hole CH1 and may not overlap the second contact hole CH2 in a plan view. The second alignment electrode ALE2 may completely overlap the first contact hole CH1 and may not overlap the second contact hole CH2 in a plan view. The second alignment electrode ALE2 may overlap the first edge of the first conductive pattern CP1 and the first contact hole CH1 on the first node N1 in a plan view. For example, the width of the second alignment electrode ALE2 along the second direction in an area overlapping the first gate electrode GE1 may be narrower than the width of the second alignment electrode ALE2 along the second direction in an area overlapping the second source area SE2.

As the second alignment electrode ALE2 to which the voltage of the second driving power supply VSS is to be applied is partially disposed on the first node N1 of the first sub-pixel SPX1, a phenomenon in which a change in voltage (or signal) applied to the first node N1 of the first sub-pixel SPX1 causes a change in voltage applied to the first node N1 of an adjacent sub-pixel SPX can be reduced.

In an embodiment, a conductive pattern (or a bridge pattern) positioned on a first node of each sub-pixel (e.g., a connection point at which a gate electrode of a first transistor and a source electrode of a second transistor are electrically connected to each other) may overlap an alignment electrode to which a certain voltage is to be applied, whereby coupling capacitance (or parasitic capacitance) occurring on the first nodes of adjacent sub-pixels may be reduced, thus providing a display device with improved reliability.

In an embodiment, the capacitance of a storage capacitor of each sub-pixel may be enhanced, whereby it is possible to provide a display device with improved reliability.

The effects of the present disclosure are not limited by the foregoing, and other various effects are anticipated herein.

While various exemplary embodiments have been described above, those skilled in the art will appreciate that various modifications, additions and substitutions are possible without departing from the scope of the present disclosure.

Therefore, the embodiments disclosed in this specification are only for illustrative purposes rather than limiting the technical spirit of the present disclosure. The scope of the present disclosure must be defined by the accompanying claims.

What is claimed is:

1. A display device, comprising:
a first sub-pixel, a second sub-pixel, and a third sub-pixel disposed adjacent to each other,
wherein each of the first sub-pixel, the second sub-pixel, and the third sub-pixel comprises:
a pixel circuit layer including a first transistor, a second transistor, and a third transistor that are disposed on a substrate,
a bridge pattern disposed on a gate electrode of the first transistor and a source electrode of the second transistor, a first end of the bridge pattern is electrically connected to the source electrode of the second transistor and a second end of the bridge pattern is electrically connected to the gate electrode of the first transistor;
a first alignment electrode and a second alignment electrode disposed on the pixel circuit layer and spaced apart from each other; and
light emitting elements disposed on the first alignment electrode and the second alignment electrode, and electrically connected to at least one of the first transistor, the second transistor, and the third transistor,
wherein the second alignment electrode is supplied with a low potential voltage and overlaps the bridge pattern in a plan view.

2. The display device according to claim 1, wherein the pixel circuit layer includes a first insulating layer, a second insulating layer, a third insulating layer, a fourth insulating layer, and a fifth insulating layer that are successively stacked on the substrate, and
wherein the source electrode of the second transistor is disposed on the first insulating layer, the gate electrode of the first transistor is disposed on the second insulating layer, the bridge pattern is disposed on the third insulating layer, and the second alignment electrode is disposed on the fifth insulating layer.

3. The display device according to claim 2, wherein the first end of the bridge pattern is electrically connected to the source electrode of the second transistor through a first contact hole formed through the second and the third insulating layers, and
wherein the second end of the bridge pattern is electrically connected to the gate electrode of the first transistor through a second contact hole formed through the third insulating layer.

4. The display device according to claim 3, wherein the second alignment electrode overlaps the first contact hole and the second contact hole.

5. The display device according to claim 3, wherein the second alignment electrode overlaps the second contact hole and does not overlap the first contact hole.

6. The display device according to claim 3, wherein the second alignment electrode overlaps the first contact hole and does not overlap the second contact hole.

7. The display device according to claim 2, wherein each of the first sub-pixel, the second sub-pixel, and the third sub-pixel comprises:
a contact electrode disposed on the third insulating layer;
the fourth and the fifth insulating layers disposed on the contact electrode, and each including a contactor exposing the contact electrode; and
electrodes disposed on the first alignment electrode, the second alignment electrode, and the light emitting elements on the fifth insulating layer, and electrically connected to the light emitting elements.

8. The display device according to claim 7, wherein at least one electrode of the electrodes is electrically connected to the contact electrode through the contactor.

9. The display device according to claim 8,
wherein the electrodes comprise a first electrode, a second electrode, a third electrode, a fourth electrode, and a fifth electrode spaced apart from each other,
wherein the first electrode comprises an anode electrode of each of the first, the second, and the third sub-pixels, and the fifth electrode comprises a cathode electrode of the corresponding sub-pixel, and
wherein the at least one electrode comprises the first electrode.

10. The display device according to claim 9,
wherein each of the first, the second, and the third sub-pixels comprises:
a first sub-electrode disposed on a layer identical to the second electrode and electrically connected to the second electrode;
a second sub-electrode disposed on a layer identical to the third electrode and electrically connected to the third electrode;
a third sub-electrode disposed on a layer identical to the fourth electrode and electrically connected to the fourth electrode; and
a fourth sub-electrode disposed on a layer identical to the fifth electrode and electrically connected to the fifth electrode, and
wherein the fourth sub-electrode of the first sub-pixel is electrically connected to the fourth sub-electrode of the second sub-pixel.

11. The display device according to claim 10, wherein the first electrode, the second electrode, the third electrode, the fourth electrode, and the fifth electrodes, and the first sub-electrode, the second sub-electrode, the third sub-electrode, and the fourth sub-electrodes include identical material.

12. The display device according to claim 1, wherein the bridge pattern of the first sub-pixel, the bridge pattern of the third sub-pixel, and the bridge pattern of the second sub-pixel are arranged sequentially in a second direction in a plan view, and
wherein the second alignment electrode has a plate shape, extending in the second direction, and overlapping the bridge pattern of the first sub-pixel, the bridge pattern of the third sub-pixel, and the bridge pattern of the second sub-pixel.

13. The display device according to claim 12, wherein, in each of the first sub-pixel, the second sub-pixel, and the third sub-pixel, the gate electrode of the first transistor, the source electrode of the second transistor, and the bridge pattern that are electrically connected to each other form a first node, and
wherein the second alignment electrode is a shielding component to block parasitic capacitance occurring between the first nodes of the sub-pixels that are disposed adjacent to each other in the second direction.

14. The display device according to claim 1, further comprising a data line configured to transmit a data signal to each of the first sub-pixel, the second sub-pixel, and the third sub-pixel, and extending in a second direction,
wherein the data line has a width of approximately 7 μm in a first direction intersecting the second direction.

15. The display device according to claim 1, further comprising:
a first color conversion layer disposed in the first sub-pixel, and a first color filter disposed on the first color conversion layer;
a second color conversion layer disposed in the second sub-pixel, and a second color filter disposed on the second color conversion layer; and
a third color conversion layer disposed in the third sub-pixel, and a third color filter disposed on the third color conversion layer.

16. A display device, comprising:
a substrate;
a first sub-pixel, a third sub-pixel, and a second sub-pixel disposed adjacent to each other in a second direction, each including an emission area and a non-emission area, and disposed on the substrate;
a first data line configured to apply a data signal to the first sub-pixel, a second data line configured to apply a data signal to the second sub-pixel, and a third data line configured to apply a data signal to the third sub-pixel;
light emitting elements disposed in the respective emission areas of the first sub-pixel, the second sub-pixel and the third sub-pixel;
a first transistor, a second transistor, and a third transistor positioned between the substrate and the light emitting elements, and electrically connected to the light emitting elements;
a bridge pattern electrically connecting a gate electrode of the first transistor and a source electrode of the second transistor;
a first alignment electrode and a second alignment electrode positioned between the bridge pattern and the light emitting elements, and disposed to be spaced apart from each other; and
electrodes disposed on the first alignment electrode and the second alignment electrode, and electrically connected to the light emitting elements,
wherein the second alignment electrode overlaps the bridge pattern of the first sub-pixel, the bridge pattern of the second sub-pixel, and the bridge pattern of the third sub-pixel in a plan view.

17. The display device according to claim 16, wherein the first alignment electrode is a floating electrode and the second alignment electrode is supplied with a low potential voltage.

18. The display device according to claim 16, further comprising a first insulating layer, a second insulating layer, a third insulating layer, a fourth insulating layer, and a fifth insulating layer disposed between the substrate and the first alignment electrode and the second alignment electrode, and stacked sequentially on the substrate,
wherein the source electrode of the second transistor is disposed on the first insulating layer, the gate electrode of the first transistor is disposed on the second insulating layer, and the bridge pattern is disposed on the third insulating layer, and the first alignment electrode and the second alignment electrode are disposed on the fifth insulating layer,
wherein a first end of the bridge pattern is electrically connected to the source electrode of the second transistor through a first contact hole formed through the second insulating layer and the third insulating layers, and
wherein a second end of the bridge pattern is electrically connected to the gate electrode of the first transistor through a second contact hole formed through the third insulating layer.

19. The display device according to claim 18, wherein the second alignment electrode overlaps the first contact hole and the second contact hole in a plan view.

20. The display device according to claim 16,
wherein the first data line, the second data line, and the third data line are arranged sequentially in a first direction intersecting the second direction, and
wherein each of the first data line, the second data line, and the third data line has a width of approximately 7 μm in the first direction.
